(19) United States
(12) Patent Application Publication
(10) Pub. No.: US 2026/0198373 A1
(43) Pub. Date: Jul. 9, 2026

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Yoshitaka KATO, Nisshin-shi (JP); Takeshi ENDO, Nisshin-shi (JP); Masato TAKI, Nisshin-shi (JP)

(21) Appl. No.: 19/386,514

(22) Filed: Nov. 12, 2025

(30) Foreign Application Priority Data
Jan. 8, 2025 (JP) 2025-002944

(51) Int. Cl. H01L 23/047; H01L 23/373; H01L 23/498; H02M 7/537; H10D 80/20

(52) U.S. Cl. CPC H10W 76/134; H10D 80/213; H10D 80/215; H10D 80/251; H10W 40/255; H10W 70/658; H02M 7/537

(57) ABSTRACT

A semiconductor device includes a substrate, a semiconductor element, a terminal and a heat generating component. The semiconductor element is connected to a surface of the substrate. The terminal is electrically conductive and is connected to the substrate. The heat generating component is connected to the substrate and generates heat when an electric current flows therethrough. The heat generating component is disposed at a position overlapping with the terminal when projected in a thickness direction of the substrate.

### CROSS REFERENCE TO RELATED APPLICATION

The present application claims the benefit of priority from Japanese Patent Application No. 2025-002944 filed on Jan. 8, 2025. The entire disclosures of the above application are incorporated herein by reference.

### TECHNICAL FIELD

The present disclosure relates to a semiconductor device.

### BACKGROUND

For example, a semiconductor device including a printed board, a semiconductor chip, an interposer, and a snubber circuit has been known. The semiconductor chip is connected to the printed board through the interposer. The snubber circuit is disposed on a surface of the printed board opposite to the semiconductor chip.

### SUMMARY

According to an aspect of the present disclosure, a semiconductor device includes a substrate, a semiconductor element, a terminal and a heat generating component. The semiconductor element is connected to a surface of the substrate. The terminal is electrically conductive and is connected to the substrate. The heat generating component is connected to the substrate and generates heat when an electric current flows therethrough. The heat generating component may be disposed at a position overlapping with the terminal when the heat generating component is projected in a thickness direction of the substrate.

### BRIEF DESCRIPTION OF DRAWINGS

Objects, features and advantages of the present disclosure will become more apparent from the following detailed description made with reference to the accompanying drawings, in which:

FIG. 1 is a top view of a semiconductor device according to a first embodiment;

FIG. 2 is a cross-sectional view of the semiconductor device taken along a line II-II in FIG. 1;

FIG. 3 is a cross-sectional view of the semiconductor device taken along a line III-III in FIG. 1;

FIG. 4 is a circuitry diagram of the semiconductor device according to the first embodiment;

FIG. 5 is a cross-sectional view of a semiconductor device according to a comparative example 1;

FIG. 6 is a diagram showing a temperature distribution in the semiconductor device according to the comparative example 1;

FIG. 7 is a diagram showing temperatures of resistive elements in the semiconductor devices of the comparative example 1 and the first embodiment;

FIG. 8 is a diagram showing a temperature distribution in the semiconductor device according to the first embodiment;

FIG. 9 is a cross-sectional view of a semiconductor device according to a comparative example 2;

FIG. 10 is a top view of a semiconductor device according to a second embodiment;

FIG. 11 is a cross-sectional view of the semiconductor device taken along a line XI-XI in FIG. 10;

FIG. 12 is a cross-sectional view of the semiconductor device taken along a line XII-XII in FIG. 10;

FIG. 13 is a top view of a semiconductor device according to a third embodiment;

FIG. 14 is a cross-sectional view of the semiconductor device taken along a line XIV-XIV in FIG. 13;

FIG. 15 is a top view of a semiconductor device according to a fourth embodiment;

FIG. 16 is a circuitry diagram of the semiconductor device according to the fourth embodiment;

FIG. 17 is a top view of a semiconductor device according to a fifth embodiment;

FIG. 18 is a cross-sectional view of a semiconductor device according to a sixth embodiment;

FIG. 19 is a cross-sectional view of a semiconductor device according to a seventh embodiment;

FIG. 20 is a cross-sectional view of a semiconductor device according to an eighth embodiment;

FIG. 21 is a cross-sectional view of a semiconductor device according to a ninth embodiment;

FIG. 22 is a cross-sectional view of a semiconductor device according to a tenth embodiment;

FIG. 23 is a cross-sectional view of a semiconductor device according to an eleventh embodiment;

FIG. 24 is a cross-sectional view of a semiconductor device according to a twelfth embodiment;

FIG. 25 is a cross-sectional view of a semiconductor device according to a thirteenth embodiment;

FIG. 26 is a cross-sectional view of a semiconductor device according to a fourteenth embodiment;

FIG. 27 is a cross-sectional view of a semiconductor device according to a fifteenth embodiment;

FIG. 28 is a circuitry diagram of the semiconductor device according to the fifteenth embodiment;

FIG. 29 is a top view of a semiconductor device according to a sixteenth embodiment;

FIG. 30 is a cross-sectional view of the semiconductor device taken along a line XXX-XXX in FIG. 29;

FIG. 31 is a cross-sectional view of the semiconductor device taken along a line XXXI-XXXI in FIG. 29;

FIG. 32 is a top view of a semiconductor device according to a seventeenth embodiment; and

FIG. 33 is a cross-sectional view of the semiconductor device taken along a line XXXIII-XXXIII in FIG. 32.

### DETAILED DESCRIPTION

As a related art, there is a semiconductor device including a printed board, a semiconductor chip, an interposer, and a snubber circuit. The semiconductor chip is connected to the printed board through the interposer. The snubber circuit is disposed on a surface of the printed board opposite to the semiconductor chip. When such a semiconductor device is operated, the semiconductor chip and a heat generating component such as a snubber circuit generate heat. The amount of heat generated in the semiconductor chip is greater than the amount of heat generated in the heat generating component. Furthermore, when the heat generating component is projected in a thickness direction of the printed board, the projected heat generating component may overlap with the semiconductor chip. In this case, the heat generated in the semiconductor chip is easily conducted to the heat generating component through the interposer and the printed board. Since the temperature of the heat generating component easily increases, a thermal stress to the heat generating component is likely to increase. Therefore, in such a semiconductor device, the heat generating component such as a snubber circuit is likely to be damaged.

The present disclosure provides a semiconductor device that suppresses the increase in temperature of a heat generating component.

According to an aspect of the present disclosure, a semiconductor device includes a substrate, a semiconductor element, a terminal, and a heat generating component. The semiconductor element is connected to a surface of the substrate. The terminal is electrically conductive and is connected to the substrate. The heat generating component is connected to the substrate and generates heat when an electric current flows therethrough. The heat generating component is disposed at a position overlapping with the terminal when the heat generating component is projected in a thickness direction of the substrate.

According to another aspect of the present disclosure, a semiconductor device includes a substrate, a semiconductor element, a heat dissipation member, and a heat generating component. The substrate has a first surface and a second surface opposite to the first surface in a thickness direction of the substrate. The semiconductor element is connected to the first surface of the substrate. The heat dissipation member is connected to the semiconductor element on a side opposite to the substrate and extends in a direction perpendicular to the thickness direction of the substrate. The heat generating component is connected to the second surface of the substrate and generates heat when an electric current flows therethrough. The heat generating component is disposed at a position overlapping with the heat dissipation member when the heat generating component is projected in the thickness direction of the substrate.

According to a further another aspect of the present disclosure, a semiconductor device includes a substrate, a semiconductor element, a terminal, and a heat generating component. The semiconductor element is connected to a surface of the substrate. The terminal is electrically conductive and is connected to the surface of the substrate. The heat generating component is connected to the surface of the substrate and generates heat when an electric current flows therethrough. A distance from the heat generating component to the terminal in a direction perpendicular to a thickness direction of the substrate is shorter than a distance from the heat generating component to the semiconductor element in a direction perpendicular to the thickness direction of the substrate.

Accordingly, the heat generated in the heat generating component is easily conducted to the terminal. Therefore, the heat generated in the heat generating component is easily dissipated. Furthermore, heat generated in the semiconductor element is less conducted to the heat generating component. Therefore, the increase in temperature of the heat generating component is suppressed.

Hereinafter, embodiments of the present disclosure will be described with reference to the drawings. In the following, the same or equivalent parts are denoted by the same reference numerals throughout the embodiments, and the descriptions thereof will not be repeated.

### First Embodiment

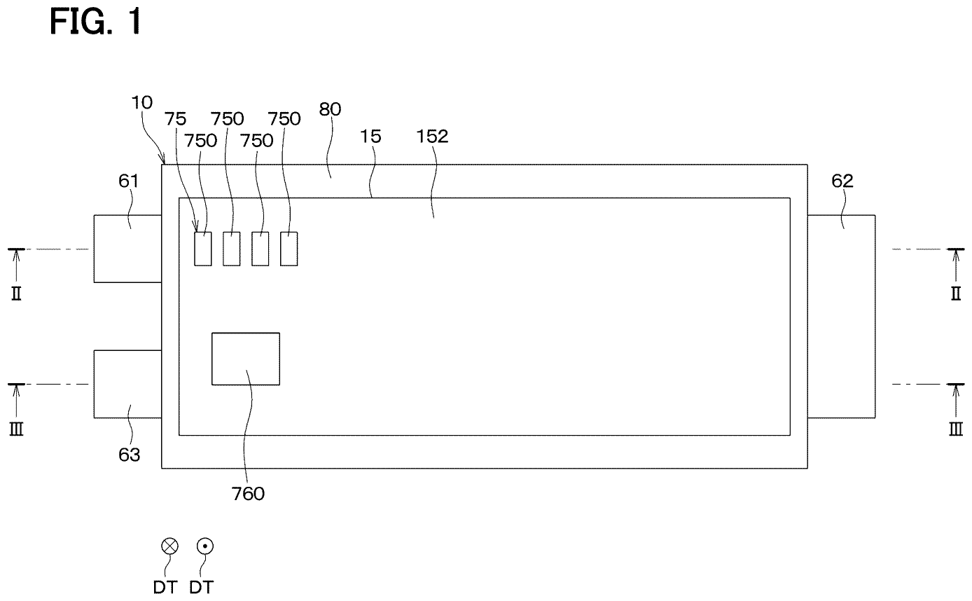

A semiconductor device of this embodiment suppresses the increase in temperature of a heat generating component. Specifically, as shown in FIGS. 1 through 4, a semiconductor device 10 includes a substrate 15, a first semiconductor element 21, a bonding material 31 for the first semiconductor element 21, a first gate wiring 41, a second semiconductor element 22, a bonding material 32 for the second semiconductor element 22, a second gate wiring 42, and a first heat dissipation member 51. The semiconductor device 10 further includes a third semiconductor element 23, a bonding material 33 for the third semiconductor element 23, a third gate wiring 43, a fourth semiconductor element 24, a bonding material 34 for the fourth semiconductor element 24, a fourth gate wiring 44, and a second heat dissipation member 52. Furthermore, the semiconductor device 10 includes a P terminal 61, a bonding material 71 for the P terminal 61, an O terminal 62, a bonding material 72 for the O terminal 62, an N terminal 63, a bonding material 73 for the N terminal 63, a snubber circuit 75, an encapsulating resin 80, a thermal conductive member 85, and a cooler 90.

The substrate 15 is a printed board made of glass epoxy resin, such as FR4. FR4 is an abbreviation for Flame Retardant Type 4. In the following description, a thickness direction of the substrate 15 will be simply referred to as the thickness direction DT.

As shown in FIGS. 1 through 3, the substrate 15 has a substrate front surface 150 and a substrate back surface 152. The substrate front surface 150 is the surface of the substrate 15 on one side in the thickness direction DT. The substrate back surface 152 is the surface of the substrate 15 on the other side in the thickness direction DT, and is opposite to the substrate front surface 150. The substrate front surface 150 will also be referred to as a first surface of the substrate 15, and the substrate back surface 152 will also be referred to as a second surface of the substrate 15.

The first semiconductor element 21 is, for example, a metal oxide semiconductor field effect transistor (MOSFET) made by using silicon (Si) or silicon carbide (SiC).

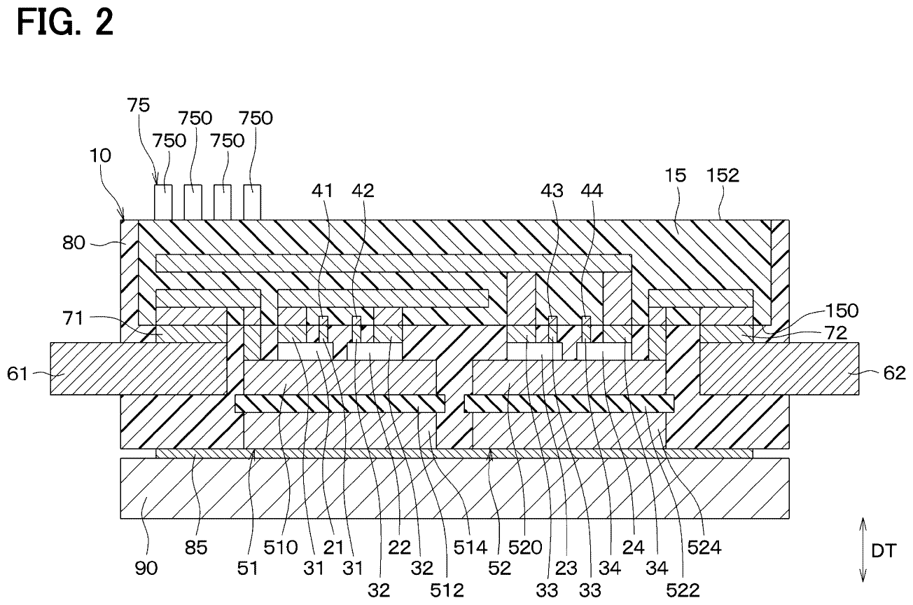

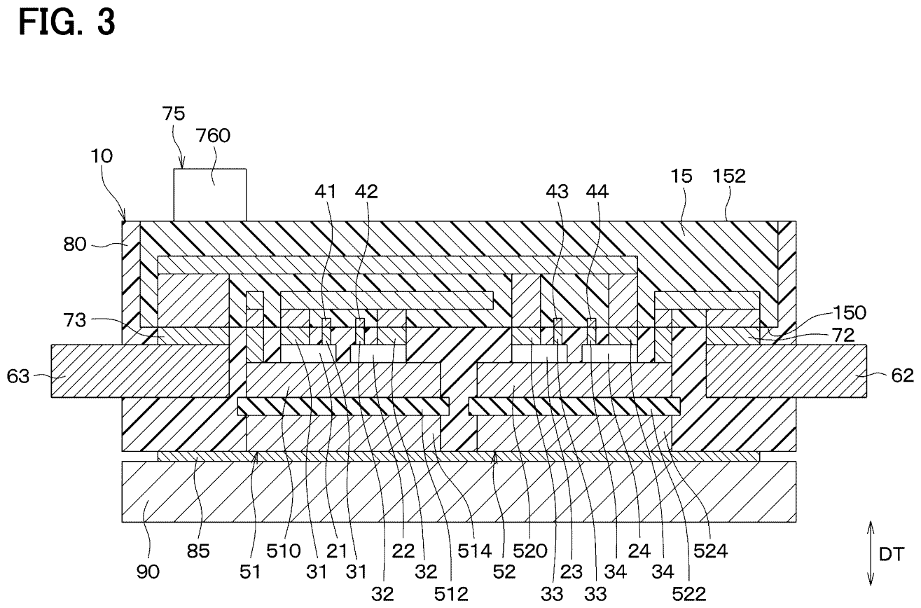

As shown in FIGS. 2 and 3, the first semiconductor element 21 has a source electrode that is connected to the substrate front surface 150 through the first semiconductor element bonding material 31. The first semiconductor element 21 has a gate electrode that is connected to the first gate wiring 41 disposed in the substrate 15 through the first semiconductor element bonding material 31. The first semiconductor element bonding material 31 is, for example, provided by solder or sintered silver.

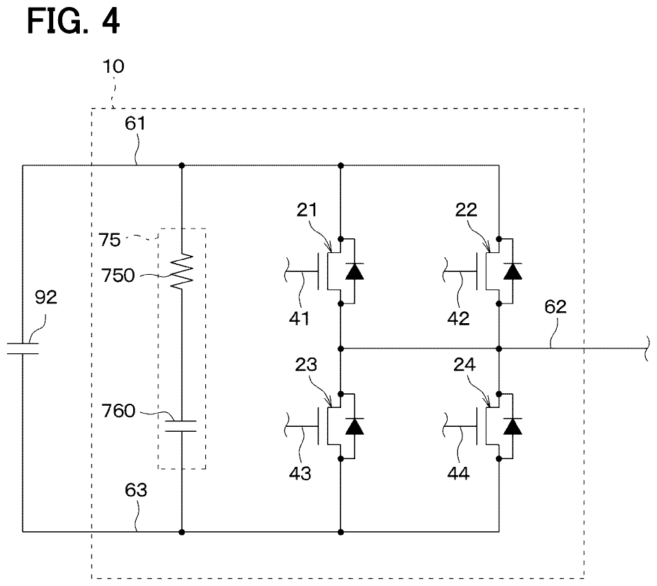

The second semiconductor element 22 is, for example, a MOSFET made by using Si or SiC. The second semiconductor element 22 has a source electrode that is connected to the substrate front surface 150 through the second semiconductor element bonding material 32. As shown in FIG. 4, the second semiconductor element 22 is connected in parallel to the first semiconductor element 21. Returning to FIGS. 2 and 3, the second semiconductor element 22 has a gate electrode that is connected to the second gate wiring 42 disposed in the substrate 15 through the second semiconductor element bonding material 32. The second semiconductor element bonding material 32 is, for example, provided by solder or sintered silver.

The first heat dissipation member 51 dissipates heats generated in the first semiconductor element 21 and the second semiconductor element 22 to the outside. The first heat dissipation member 51 is, for example, an insulating circuit board. The first heat dissipation member 51 includes a first heat dissipation portion 510, a first insulating portion 512 and a second heat dissipation portion 514.

The first heat dissipation portion 510 is made of copper or the like. As a result, the first heat dissipation portion 510 is electrically conductive and has a relatively high thermal conductivity. The first heat dissipation portion 510 has a plate shape. The first heat dissipation portion 510 is connected to the drain electrode of the first semiconductor element 21 and the drain electrode of the second semiconductor element 22.

The first insulating portion 512 is made of ceramics or the like. As a result, the first insulating portion 512 is electrically insulating. The first insulating portion 512 has a plate shape. The first insulating portion 512 is connected to the first heat dissipation portion 510 on a side opposite to the first semiconductor element 21 and the second semiconductor element 22 in the thickness direction DT.

The second heat dissipation portion 514 is made of copper or the like. As a result, the second heat dissipation portion 514 is electrically conductive and has a relatively high thermal conductivity. The second heat dissipation portion 514 has a plate shape. The second heat dissipation portion 514 is connected to the first insulating portion 512 on a side opposite to the first heat dissipation portion 510 in the thickness direction DT. Therefore, when the first semiconductor element 21 and the second semiconductor element 22 generate heat, the heats from the first semiconductor element 21 and the second semiconductor element 22 are conducted to the first heat dissipation member 51 and dissipated.

The third semiconductor element 23 is, for example, a MOSFET made by using Si or SiC. The third semiconductor element 23 has a source electrode that is connected to the substrate front surface 150 through the third semiconductor element bonding material 33. The third semiconductor element 23 has a gate electrode that is connected to the third gate wiring 43 disposed in the substrate 15 through the third semiconductor element bonding material 33. The third semiconductor element bonding material 33 is, for example, provided by solder or sintered silver.

The fourth semiconductor element 24 is, for example, a MOSFET made of Si or SiC. The fourth semiconductor element 24 has a source electrode that is connected to the substrate front surface 150 through the fourth semiconductor element bonding material 34. As shown in FIG. 4, the fourth semiconductor element 24 is connected in parallel to the third semiconductor element 23. Returning to FIGS. 2 and 3, the fourth semiconductor element 24 has a gate electrode that is connected to the fourth gate wiring 44 disposed in the substrate 15 through the fourth semiconductor element bonding material 34. The fourth semiconductor element bonding material 34 is, for example, provided by solder or sintered silver.

The second heat dissipation member 52 dissipates heats generated in the third semiconductor element 23 and the fourth semiconductor element 24 to the outside. The second heat dissipation member 52 is, for example, an insulating circuit board. The second heat dissipation member 52 has a third heat dissipation portion 520, a second insulating portion 522 and a fourth heat dissipation portion 524.

The third heat dissipation portion 520 is made of copper or the like. As a result, the third heat dissipation portion 520 is electrically conductive and has a relatively high thermal conductivity. The third heat dissipation portion 520 has a plate shape. The third heat dissipation portion 520 is connected to the drain electrode of the third semiconductor element 23 and the drain electrode of the fourth semiconductor element 24.

The second insulating portion 522 is made of ceramics or the like. As a result, the second insulating portion 522 is electrically insulating. The second insulating portion 522 has a plate shape. The second insulating portion 522 is connected to the third heat dissipation portion 520 on a side opposite to the third semiconductor element 23 and the fourth semiconductor element 24 in the thickness direction DT.

The fourth heat dissipation portion 524 is made of copper or the like. As a result, the fourth heat dissipation portion 524 is electrically conductive and has a relatively high thermal conductivity. The fourth heat dissipation portion 524 has a plate shape. The fourth heat dissipation portion 524 is connected to the second insulating portion 522 on a side opposite to the third heat dissipation portion 520 in the thickness direction DT. Therefore, when the third semiconductor element 23 and the fourth semiconductor element 24 generate heats, the heats from the third semiconductor element 23 and the fourth semiconductor element 24 are conducted to the second heat dissipation member 52 and dissipated.

The P terminal 61 is made of metal or the like and is therefore electrically conductive. The P terminal 61 has a plate shape, for example. As shown in FIG. 2, the P terminal 61 is connected to the substrate front surface 150 through the P terminal bonding material 71 in the thickness direction DT. The P terminal bonding material 71 is, for example, provided by solder or sintered silver. In addition, the P terminal 61 is connected to the drain electrode of the first semiconductor element 21 and the drain electrode of the second semiconductor element 22 through the P terminal bonding material 71, vias and wiring layers disposed in the substrate 15, a bonding material, and the first heat dissipation portion 510. Therefore, one end of the P terminal 61 is connected to the drain electrode of the first semiconductor element 21 and the drain electrode of the second semiconductor element 22, as shown in FIG. 4.

The other end of the P terminal 61 is connected to one end of the supply capacitor 92. The supply capacitor 92 is disposed outside the semiconductor device 10. The supply capacitor 92 is charged with power from a power source (not shown). The supply capacitor 92 supplies the charged power to the semiconductor device 10 through the P terminal 61.

The O terminal 62 is made of metal or the like and is therefore electrically conductive. The O terminal 62 has a plate shape, for example. As shown in FIGS. 2 and 3, the O terminal 62 is connected to the substrate front surface 150 through the O terminal bonding material 72 in the thickness direction DT. The O terminal bonding material 72 is, for example, provided by solder or sintered silver.

The O terminal 62 is connected to the source electrode of the first semiconductor element 21 through the O terminal bonding material 72, a via and a wiring layer disposed in the substrate 15, and the first semiconductor element bonding material 31. The O terminal 62 is also connected to the source electrode of the second semiconductor element 22 through the O terminal bonding material 72, a via and a wiring layer disposed in the substrate 15, and the second semiconductor element bonding material 32. The O terminal 62 is also connected to the drain electrode of the third semiconductor element 23 and the drain electrode of the fourth semiconductor element 24 via the O terminal bonding material 72, vias and wiring layers disposed in the substrate 15, the bonding material, and the third heat dissipation portion 520. Therefore, as shown in FIG. 4, one end of the O terminal 62 is connected to the source electrode of the first semiconductor element 21, the source electrode of the second semiconductor element 22, the drain electrode of the third semiconductor element 23, and the drain electrode of the fourth semiconductor element 24.

Furthermore, the other end of the O terminal 62 is connected to a load (not shown). The O terminal 62 outputs an electric current to the load according to the on and off states of the first semiconductor element 21, the second semiconductor element 22, the third semiconductor element 23, and the fourth semiconductor element 24.

Returning to FIG. 3, the N terminal 63 is connected to the substrate front surface 150 in the thickness direction DT through the N terminal bonding material 73. The N terminal bonding material 73 is, for example, provided by solder or sintered silver. The N terminal 63 is connected to the source electrode of the third semiconductor element 23 through the N terminal bonding material 73, a via and a wiring layer disposed in the substrate 15, and the third semiconductor element bonding material 33. The N terminal 63 is connected to the source electrode of the fourth semiconductor element 24 through the N terminal bonding material 73, a via and a wiring layer disposed in the substrate 15, and the fourth semiconductor element bonding material 34. Therefore, as shown in FIG. 4, one end of the N terminal 63 is connected to the source electrode of the third semiconductor element 23 and the source electrode of the fourth semiconductor element 24. Furthermore, the other end of the N terminal 63 is connected to the other end of the supply capacitor 92.

The snubber circuit 75 receives power from the supply capacitor 92 and supplies the received power into the semiconductor device 10. The snubber circuit 75 shortens the current path, as compared to a case where the power is supplied from the supply capacitor 92 to the semiconductor device 10, thereby suppressing an increase in inductance. For example, the snubber circuit 75 includes a resistive element 750 and a capacitive element 760.

The resistive element 750 corresponds to a heat generating component. The resistive element 750 is an electric resistor that generates heat when an electric current flows therethrough. As shown in FIGS. 1 and 2, the resistive element 750 is connected to the substrate back surface 152 in the thickness direction DT. One end of the resistive element 750 is connected to the P terminal 61 through via and wiring layer (not shown) disposed in the substrate 15. Furthermore, when the resistive element 750 is projected in the thickness direction DT, the projected resistive element 750 overlaps with the P terminal 61. When the resistive element 750 is projected in the thickness direction DT, the projected resistive element 750 does not overlap with the first semiconductor element 21, the second semiconductor element 22, the third semiconductor element 23, and the fourth semiconductor element 24.

One end of the resistive element 750 is connected to the drain electrode of the first semiconductor element 21 and the drain electrode of the second semiconductor element 22 through vias and wiring layers (not shown) disposed in the substrate 15. Furthermore, as shown in FIG. 4, the resistive element 750 is connected in parallel to the first semiconductor element 21 and the second semiconductor element 22.

The capacitive element 760 is a capacitor. As shown in FIGS. 1 and 3, the capacitive element 760 is connected to the substrate back surface 152 in the thickness direction DT. One end of the capacitive element 760 is connected to the other end of the resistive element 750 through a via and a wiring layer (not shown) disposed in the substrate 15. Furthermore, as shown in FIG. 4, the capacitive element 760 is connected in series with the resistive element 750.

Returning to FIGS. 1 and 3, the other end of the capacitive element 760 is connected to the source electrode of the third semiconductor element 23 and the source electrode of the fourth semiconductor element 24 through vias and wiring layers (not shown) disposed in the substrate 15. Furthermore, as shown in FIG. 4, the capacitive element 760 is connected in parallel to the third semiconductor element 23 and the fourth semiconductor element 24.

Returning to FIGS. 2 and 3, the encapsulating resin 80 corresponds to a covering part and is made of a resin. The encapsulating resin 80 covers the substrate 15, the first semiconductor element 21, the first semiconductor element bonding material 31, and the first gate wiring 41. The encapsulating resin 80 covers the second semiconductor element 22, the second semiconductor element bonding material 32, the second gate wiring 42, and the first heat dissipation member 51. The encapsulating resin 80 also covers the third semiconductor element 23, the third semiconductor element bonding material 33, the third gate wiring 43, the fourth semiconductor element 24, the fourth semiconductor element bonding material 34, the fourth gate wiring 44, and the second heat dissipation member 52. Furthermore, the encapsulating resin 80 covers a part of the P terminal 61, the P terminal bonding material 71, a part of the O terminal 62, the O terminal bonding material 72, a part of the N terminal 63, and the N terminal bonding material 73.

The substrate back surface 152 is exposed from the encapsulating resin 80. The surface of the second heat dissipation portion 514 opposite to the first insulating portion 512 is exposed from the encapsulating resin 80. The surface of the fourth heat dissipation portion 524 opposite to the second insulating portion 522 is exposed from the encapsulating resin 80. The P terminal 61, the O terminal 62, and the N terminal 63 protrude from the encapsulating resin 80 in directions perpendicular to the thickness direction DT.

The thermal conductive member 85 is made of a thermal interface material (TIM). Therefore, the thermal conductivity of the thermal conductive member 85 is relatively high.

The thermal conductive member 85 is formed into a gel form, a sheet or a clay form. The thermal conductive member 85 is connected to the exposed surface of the second heat dissipation portion 514 and the exposed surface of the fourth heat dissipation portion 524 in the thickness direction DT. The thermal conductive member 85 is connected to the surface of the encapsulating resin 80 adjacent to the exposed surface of the second heat dissipation portion 514 and the exposed surface of the fourth heat dissipation portion 524 in the thickness direction DT. When the thermal conductive member 85 is projected in the thickness direction DT, the projected thermal conductive member 85 overlaps with the P terminal 61 and the resistive element 750. When the thermal conductive member 85 is projected in the thickness direction DT, the projected thermal conductive member 85 overlaps with the first semiconductor element 21 and the second semiconductor element 22. When the thermal conductive member 85 is projected in the thickness direction DT, the projected thermal conductive member 85 overlaps with the third semiconductor element 23 and the fourth semiconductor element 24.

The cooler 90 is disposed on the substrate front surface 150 side in the semiconductor device 10. The cooler 90 is connected to the thermal conductive member 85 on a side opposite to the encapsulating resin 80. As a result, the cooler 90 cools the inside of the semiconductor device 10. When the cooler 90 is projected in the thickness direction DT, the projected cooler 90 overlaps with the P terminal 61, the resistive element 750, and the thermal conductive member 85. As a result, the P terminal 61 is easily cooled. The cooler 90 is, for example, a pipe, and the inside of the semiconductor device 10 is cooled by a medium flowing in the cooler 90. Alternatively, the cooler 90 may be composed of a fin, such as a plurality of plate fins arranged side by side, a corrugate fin, or a pin fin. In this case, the fin of the cooler 90 is made of a material with a relatively high thermal conductivity, such as a metal such as copper or aluminum, or graphite.

The semiconductor device 10 of the first embodiment is configured as described above. Next, the suppression of temperature increase in the resistive element 750, which corresponds to a heat generating component, in the semiconductor device 10 will be described.

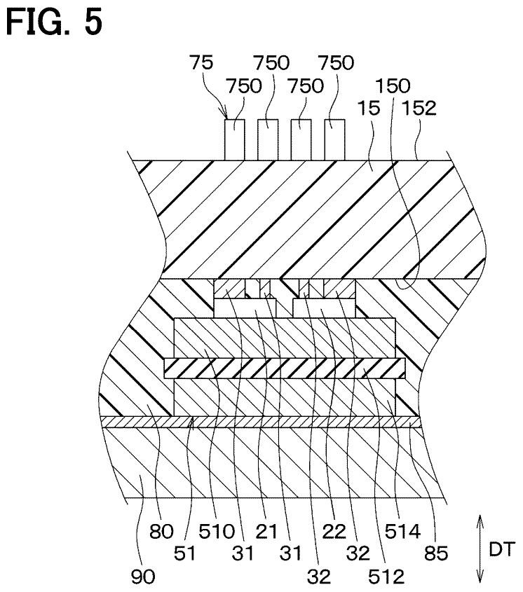

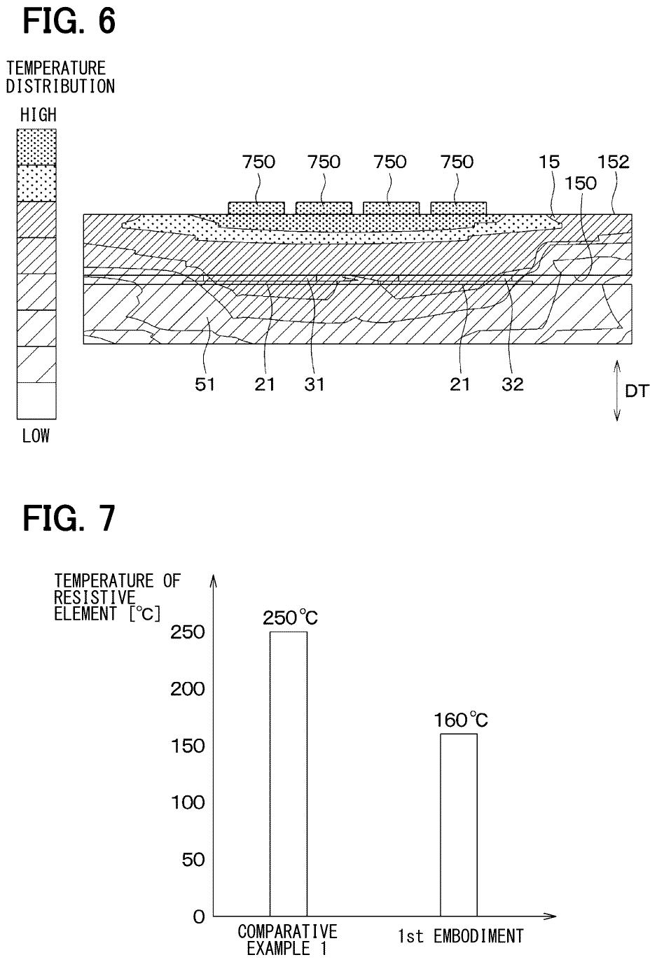

Here, in a comparative example 1 as shown in FIG. 5, when a resistive element 750 is projected in the thickness direction DT, the projected resistive element 750 overlaps with a first semiconductor element 21 and a second semiconductor element 22. It is also assumed that the first semiconductor element 21, the second semiconductor element 22, and the resistive element 750 are operating. In this case, heats generated in the first semiconductor element 21 and the second semiconductor element 22 are easily conducted to the resistive element 750 through the first semiconductor element bonding material 31, the second semiconductor element bonding material 32 and the substrate 15. Therefore, the temperature of the resistive element 750 is likely to increase. As shown in FIGS. 6 and 7, the temperature of the resistive element 750 when the semiconductor device of the comparative example 1 is operating reaches approximately 250 degrees Celsius (°C).

In contrast, in the semiconductor device 10 of the present embodiment, as shown in FIG. 2, when the resistive element 750 is projected in the thickness direction DT, the projected resistive element 750 overlaps with the P terminal 61. Furthermore, when the resistive element 750 is projected in the thickness direction DT, the projected resistive element 750 does not overlap with the first semiconductor element 21, the second semiconductor element 22, the third semiconductor element 23, and the fourth semiconductor element 24.

As such, the heat generated in the resistive element 750 is easily conducted to the P terminal 61. Therefore, the heat generated in the resistive element 750 is easily dissipated. Furthermore, heats generated in the first semiconductor element 21, the second semiconductor element 22, the third semiconductor element 23, and the fourth semiconductor element 24 are not easily conducted to the resistive element 750. Therefore, the increase in temperature of the resistive element 750, which is the heat generating component, is suppressed.

The semiconductor device 10 of the first embodiment also achieves the following effects.
(1-1) The P terminal 61 is connected to the substrate front surface 150. The resistive element 750 is connected to the substrate back surface 152. The semiconductor device 10 further includes the cooler 90. The cooler 90 is disposed on the substrate front surface 150 side and cools the P terminal 61. Furthermore, when the cooler 90 is projected in the thickness direction DT, the projected cooler 90 overlaps with the P terminal 61 and the resistive element 750.

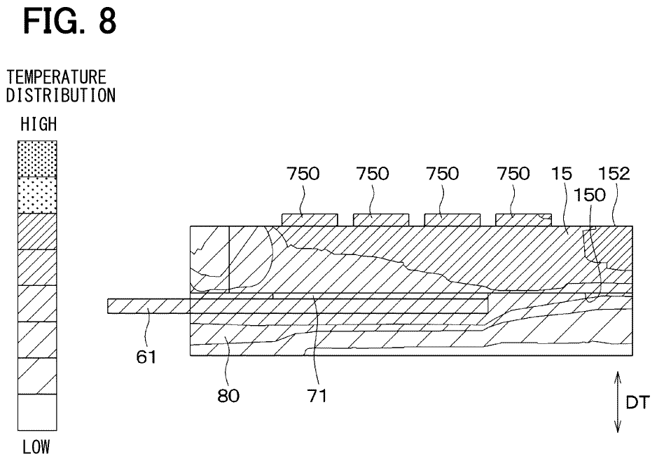

For this reason, the P terminal 61 can be easily cooled. Further, the heat generated in the resistive element 750 is easily transferred to the cooler 90 through the P terminal 61. Therefore, as shown in FIGS. 7 and 8, the temperature of the resistive element 750 is approximately 160° C. when the semiconductor device 10 of the present embodiment is operating. In the semiconductor device 10 of the present embodiment, the temperature of the resistive element 750 is lower than that of the comparative example 1 by 90° C. Therefore, the increase in temperature of the resistive element 750 is suppressed.

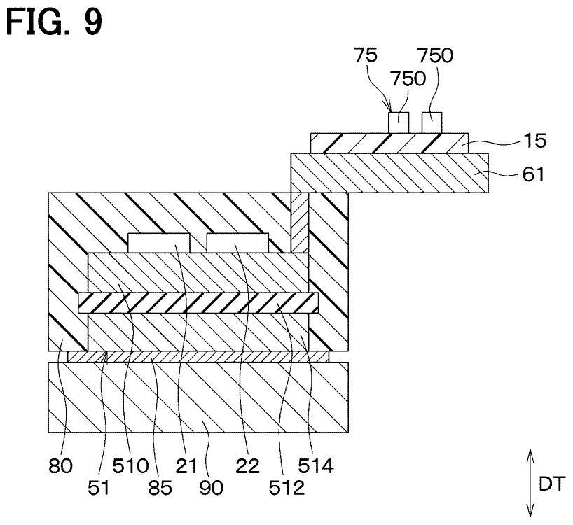

FIG. 9 shows a comparative example 2 in which a P terminal 61 is connected to a first heat dissipation portion 510 through a bonding material, and a substrate 15 is connected to a P terminal 61. Such a configuration is, for example, disclosed in JP 5558645 B2, which corresponds to US2016/0344279A1. In the device of the comparative example 2, a resistive element 750 is connected to the surface of the substrate 15 on a side opposite to the P terminal 61. Furthermore, in the device of the comparative example 2, when the cooler 90 is projected in thickness direction DT, the projected cooler 90 does not overlap with the P terminal 61 and the resistive element 750. Therefore, the path of heat transferred from the resistive element 750 to the cooler 90 through the P terminal 61 is relatively long. As such, in the device of the comparative example 2, the temperature of the resistive element 750 easily increases.

In contrast, in the semiconductor device 10 of the first embodiment, when the cooler 90 is projected in the thickness direction DT, the projected cooler 90 overlaps with the P terminal 61 and the resistive element 750. As a result, the path of heat transferred from the resistive element 750 to the cooler 90 through the P terminal 61 is relatively short. Therefore, as compared to the device of the comparative example 2, the increase in temperature of the resistive element 750 is suppressed.
(1-2) The semiconductor device 10 includes the encapsulating resin 80 and the thermal conductive member 85. The encapsulating resin 80 covers the substrate 15, the first semiconductor element 21, the second semiconductor element 22, the third semiconductor element 23, the fourth semiconductor element 24, the P terminal 61, and the like. The thermal conductive member 85 is connected to the encapsulating resin 80 and the cooler 90. When the P terminal 61 is projected in the thickness direction DT, the projected P terminal 61 overlaps with the thermal conductive member 85.

As such, the heat from the P terminal 61 is easily transferred to the cooler 90 through the encapsulating resin 80 and the thermal conductive member 85. Therefore, the heat generated in the resistive element 750 is easily transferred to the cooler 90 through the P terminal 61, the encapsulating resin 80 and the thermal conductive member 85. Since the heat generated in the resistive element 750 is easily dissipated, the increase in temperature of the resistive element 750 is suppressed.

### Second Embodiment

In a second embodiment, the configurations of the P terminal 61, the N terminal 63, and the resistive element 750 are different from those in the first embodiment. The other configurations are similar to those of the first embodiment.

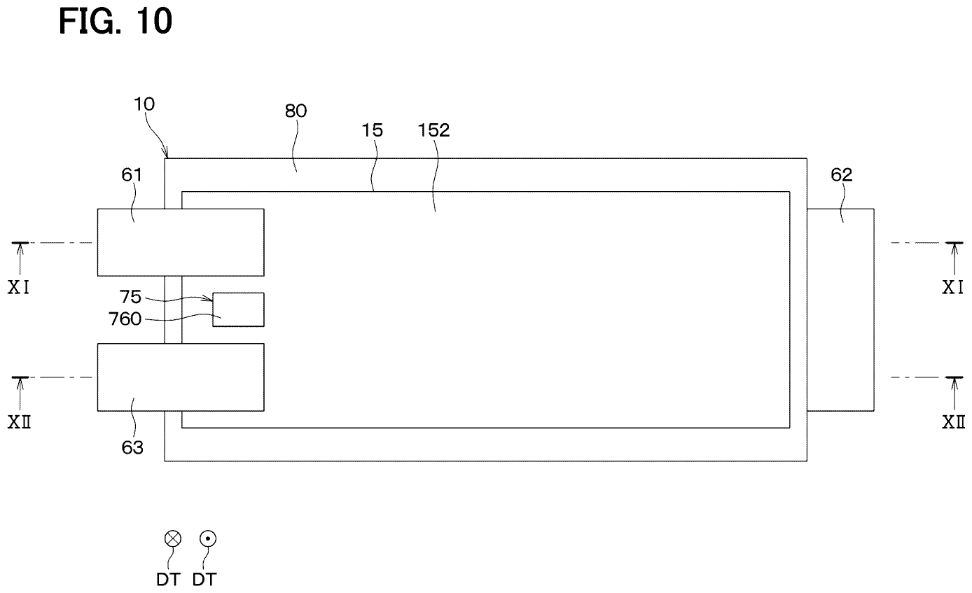

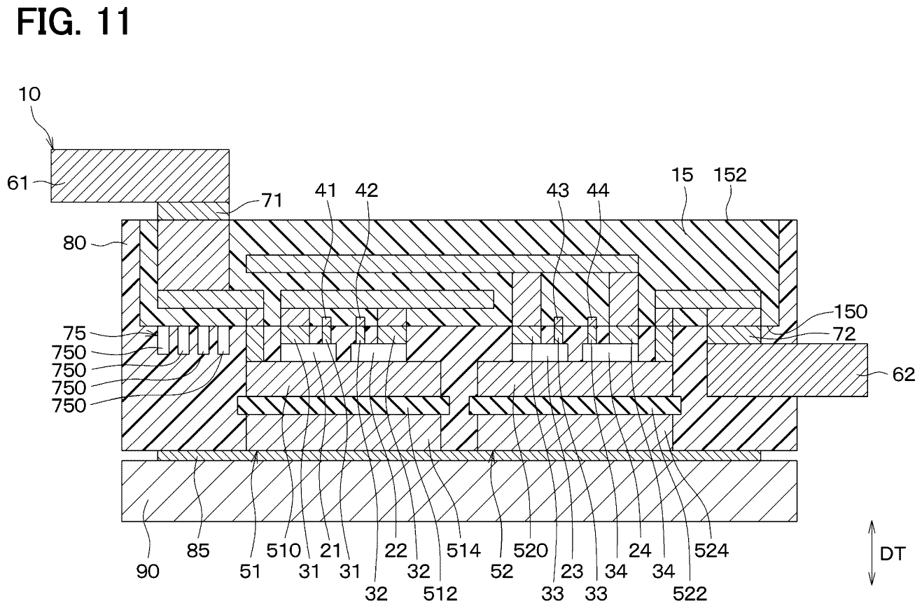

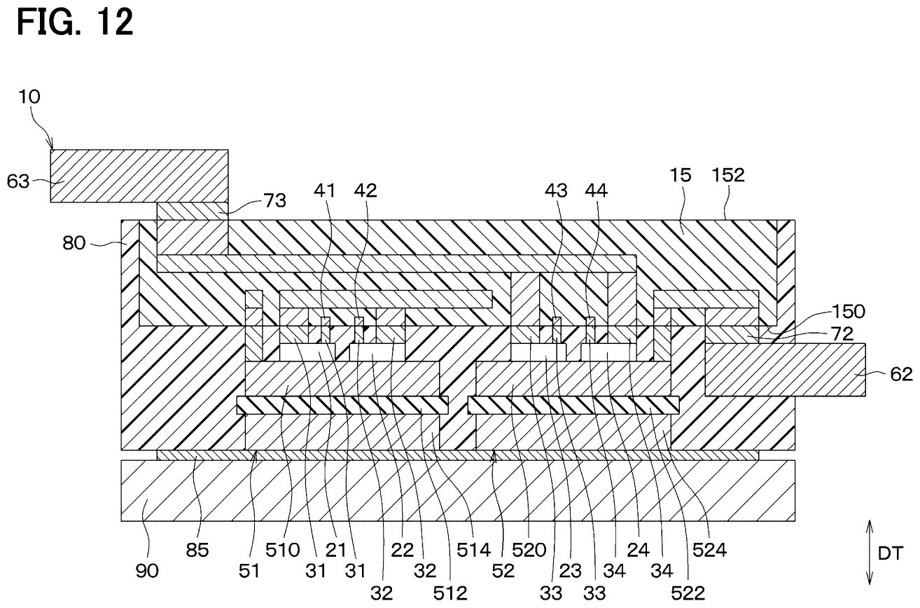

Specifically, as shown in FIGS. 10 and 11, the P terminal 61 is connected to the substrate back surface 152 in the thickness direction DT through the P terminal bonding material 71, in place of the substrate front surface 150. As shown in FIGS. 10 and 12, the N terminal 63 is connected to the substrate back surface 152 in the thickness direction DT through the N terminal bonding material 73, in place of the substrate front surface 150. As shown in FIG. 11, the resistive element 750 is connected to the substrate front surface 150 in the thickness direction DT, in place of the substrate back surface 152.

The semiconductor device 10 of the second embodiment is configured as described above. The second embodiment achieves effects similar to the effects achieved by the first embodiment.

### Third Embodiment

In a third embodiment, the configuration of the capacitive element 760 is different from that in the second embodiment. The other configurations are similar to those of the second embodiment.

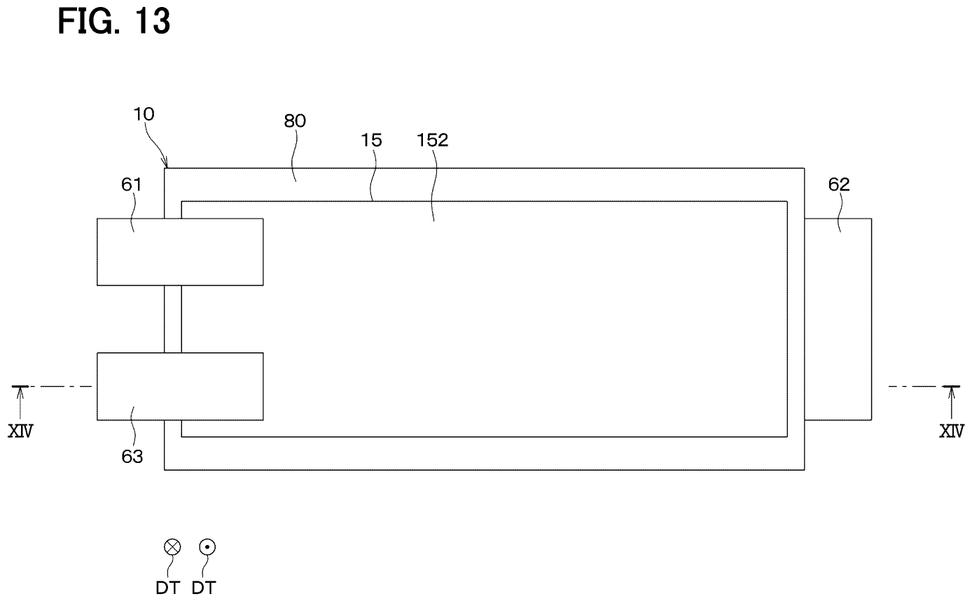

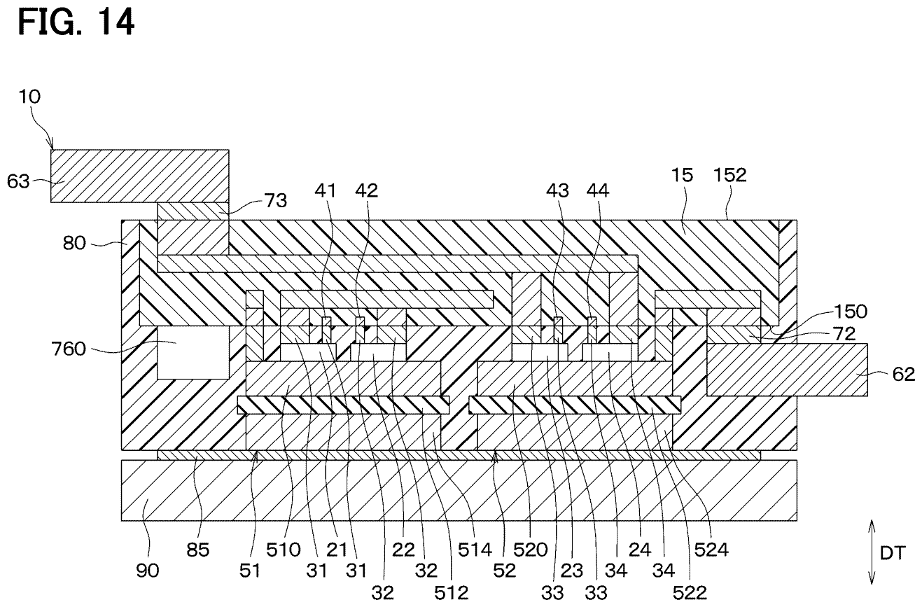

Specifically, as shown in FIGS. 13 and 14, the capacitive element 760 is connected to the substrate front surface 150 in the thickness direction DT, in place of the substrate back surface 152.

The semiconductor device 10 of the third embodiment is configured as described above. The third embodiment achieves effects similar to the effects achieved by the second embodiment.

### Fourth Embodiment

In a fourth embodiment, the semiconductor device 10 includes a first P terminal 611 and a second P terminal 612, in place of the P terminal 61. Furthermore, the configuration of the snubber circuit 75 of the semiconductor device 10 is different from that of the first embodiment. The other configurations are similar to those of the first embodiment.

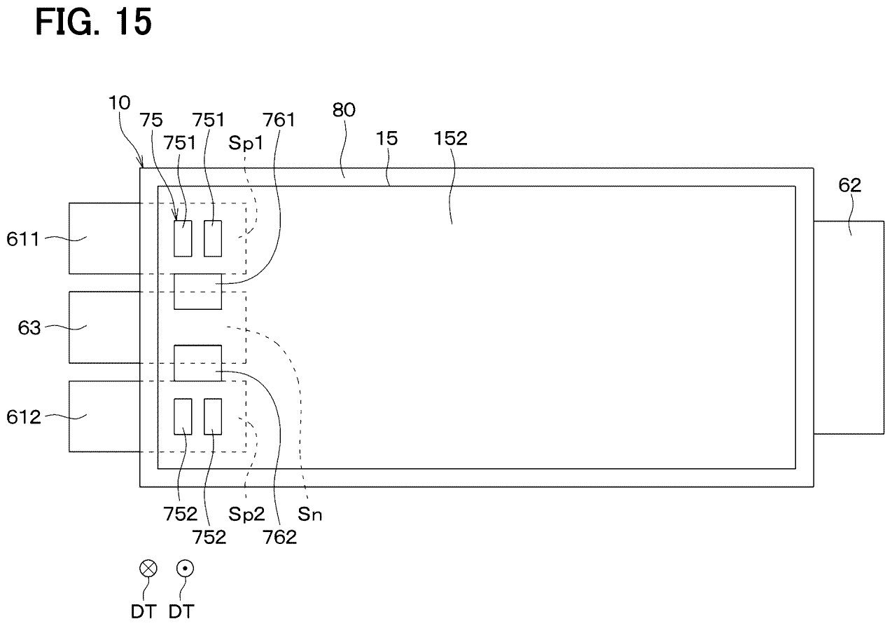

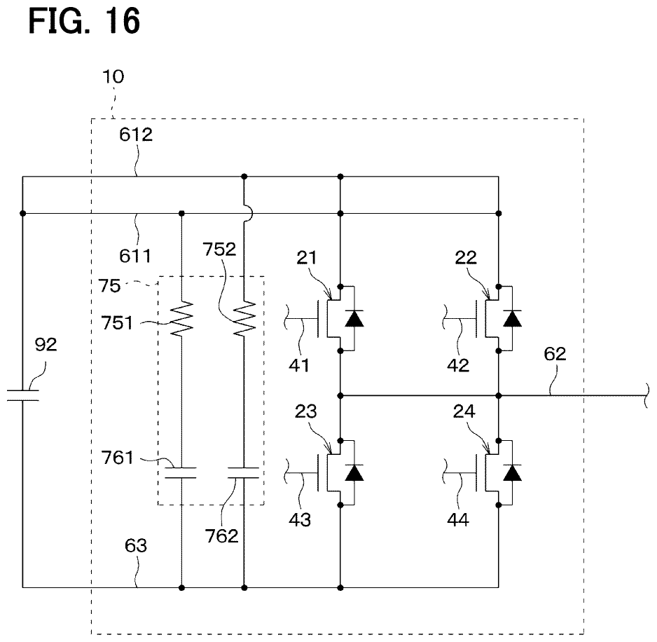

The first P terminal 611 corresponds to the P terminal 61. The first P terminal 611 is made of metal or the like, and is therefore electrically conductive. As shown in FIGS. 15 and 16, the first P terminal 611 has a plate shape, for example. The first P terminal 611 is connected to the substrate front surface 150 in the thickness direction DT through a bonding material. In addition, the first P terminal 611 is connected to the drain electrode of the first semiconductor element 21 and the drain electrode of the second semiconductor element 22 through the bonding material, vias and wiring layers disposed in the substrate 15, and the first heat dissipation portion 510. Therefore, as shown in FIG. 16, one end of the first P terminal 611 is connected to the drain electrode of the first semiconductor element 21 and the drain electrode of the second semiconductor element 22. Furthermore, the other end of the first P terminal 611 is connected to one end of the supply capacitor 92.

The second P terminal 612 is made of metal or the like and is therefore electrically conductive. As shown in FIGS. 15 and 16, the second P terminal 612 has a plate shape, for example. The second P terminal 612 is connected to the substrate front surface 150 in the thickness direction DT via a bonding material. Furthermore, the second P terminal 612 is connected to the drain electrode of the first semiconductor element 21 and the drain electrode of the second semiconductor element 22 through the bonding material, vias and wiring layers disposed in the substrate 15, and the first heat dissipation portion 510. Therefore, as shown in FIG. 16, one end of the second P terminal 612 is connected to the drain electrode of the first semiconductor element 21 and the drain electrode of the second semiconductor element 22. Furthermore, the second P terminal 612 is connected in parallel to the first P terminal 611. The other end of the second P terminal 612 is connected to one end of the supply capacitor 92.

As shown in FIG. 15, the snubber circuit 75 has a first resistive element 751, a second resistive element 752, a first capacitive element 761 and a second capacitive element 762, in place of the resistive element 750 and the capacitive element 760.

The first resistive element 751 corresponds to the heat generating component. The first resistive element 751 is an electric resistor that generates heat when an electric current flows therethrough. The first resistive element 751 is connected to the substrate back surface 152 in the thickness direction DT. Furthermore, one end of the first resistive element 751 is connected to the first P terminal 611 through a via and a wiring layer (not shown) disposed in the substrate 15. When the first resistive element 751 is projected in the thickness direction DT, the projected first resistive element 751 overlaps with the first P terminal 611. Furthermore, when the first resistive element 751 is projected in the thickness direction DT, the projected first resistive element 751 does not overlap with the first semiconductor element 21, the second semiconductor element 22, the third semiconductor element 23, and the fourth semiconductor element 24.

One end of the first resistive element 751 is connected to the drain electrode of the first semiconductor element 21 and the drain electrode of the second semiconductor element 22 through vias and wiring layers (not shown) disposed in the substrate 15. Furthermore, as shown in FIG. 16, the first resistive element 751 is connected in parallel to the first semiconductor element 21 and the second semiconductor element 22.

The second resistive element 752 corresponds to the heat generating component. The second resistive element 752 is an electric resistor that generates heat when an electric current flows therein. As shown in FIG. 15, the second resistive element 752 is connected to the substrate back surface 152 in the thickness direction DT. Furthermore, one end of the second resistive element 752 is connected to the second P terminal 612 through a via and a wiring layer (not shown) disposed in the substrate 15. When the second resistive element 752 is projected in the thickness direction DT, the projected second resistive element 752 overlaps with the second P terminal 612. Furthermore, when the second resistive element 752 is projected in the thickness direction DT, the projected second resistive element 752 does not overlap with the first semiconductor element 21, the second semiconductor element 22, the third semiconductor element 23, and the fourth semiconductor element 24.

One end of the second resistive element 752 is connected to the drain electrode of the first semiconductor element 21 and the drain electrode of the second semiconductor element 22 through vias and wiring layers (not shown) disposed in the substrate 15. As shown in FIG. 16, the second resistive element 752 is connected in parallel to the first semiconductor element 21 and the second semiconductor element 22.

When the first resistive element 751 is projected in the thickness direction DT, the entire first resistive element 751 projected overlaps with the first P terminal 611. Furthermore, when the second resistive element 752 is projected in the thickness direction DT, the entire second resistive element 752 projected overlaps with the second P terminal 612.

The first capacitive element 761 corresponds to the capacitor. As shown in FIG. 15, the first capacitive element 761 is connected to the substrate back surface 152 in the thickness direction DT. One end of the first capacitive element 761 is connected to the other end of the resistive element 750 through a via and a wiring layer (not shown) disposed in the substrate 15. Furthermore, as shown in FIG. 16, the first capacitive element 761 is connected in series with the first resistive element 751.

The other end of the first capacitive element 761 is connected to the source electrode of the third semiconductor element 23 and the source electrode of the fourth semiconductor element 24 through vias and wiring layers (not shown) disposed in the substrate 15. Furthermore, the first capacitive element 761 is connected in parallel to the third semiconductor element 23 and the fourth semiconductor element 24.

The second capacitive element 762 corresponds to the capacitor. As shown in FIG. 15, the second capacitive element 762 is connected to the substrate back surface 152 in the thickness direction DT. One end of the second capacitive element 762 is connected to the other end of the resistive element 750 through a via and a wiring layer (not shown) disposed in the substrate 15. Furthermore, as shown in FIG. 16, the second capacitive element 762 is connected in series with the second resistive element 752.

The other end of the second capacitive element 762 is connected to the source electrode of the third semiconductor element 23 and the source electrode of the fourth semiconductor element 24 through vias and wiring layers (not shown) disposed in the substrate 15. Furthermore, the second capacitive element 762 is connected in parallel to the third semiconductor element 23 and the fourth semiconductor element 24.

Returning to FIG. 15, the area of the surface of the first P terminal 611 that faces the first resistive element 751 in the thickness direction DT is referred to as Sp1. The area of the surface of the second P terminal 612 that faces the second resistive element 752 in the thickness direction DT is referred to as Sp2. The area of the surface of the N terminal 63 that faces the first capacitive element 761 and the second capacitive element 762 in the thickness direction DT is referred to as Sn.

The sum of the area Sp1 and the area Sp2 is greater than the area Sn, that is, satisfies the relationship of Sp1+Sp2>Sn.

The semiconductor device 10 of the fourth embodiment is configured as described above. The fourth embodiment achieves effects similar to the effects achieved by the first embodiment. The fourth embodiment also achieves the following effects.
(2-1) The snubber circuit 75 includes the first resistive element 751 and the second resistive element 752. When the first resistive element 751 is projected in the thickness direction DT, the projected first resistive element 751 overlaps with the first P terminal 611. When the second resistive element 752 is projected in the thickness direction DT, the projected second resistive element 752 overlaps with the second P terminal 612. The first P terminal 611 corresponds to the first terminal. The second P terminal 612 corresponds to the second terminal.

Therefore, in a case where there are multiple heat generating components, it is possible to restrict the heat from being concentrated and conducted to one terminal. For this reason, the increases in temperature of the first P terminal 611 and the second P terminal 612 are suppressed. The heat generated in the first resistive element 751 is easily dissipated to the first P terminal 611, and the heat generated in the second resistive element 752 is easily dissipated to the second P terminal 612. Therefore, the increases in temperature of the first resistive element 751 and the second resistive element 752 are suppressed.
(2-2) The sum of the area Sp1 and the area Sp2 is greater than the area Sn, that is, satisfies the relationship of Sp1+Sp2>Sn.

Therefore, the amount of heat transferred from the first resistive element 751 to the first P terminal 611 and the amount of heat transferred from the second resistive element 752 to the second P terminal 612 are increased, as compared to a configuration that satisfies a relationship of Sp1+Sp2≤Sn. Therefore, the increase in temperature of the first resistive element 751 and the increase in temperature of the second resistive element 752 are suppressed.

### Fifth Embodiment

In a fifth embodiment, the configurations of the P terminal 61 and the N terminal 63 are different from those in the first embodiment. The other configuration are similar to those of the first embodiment.

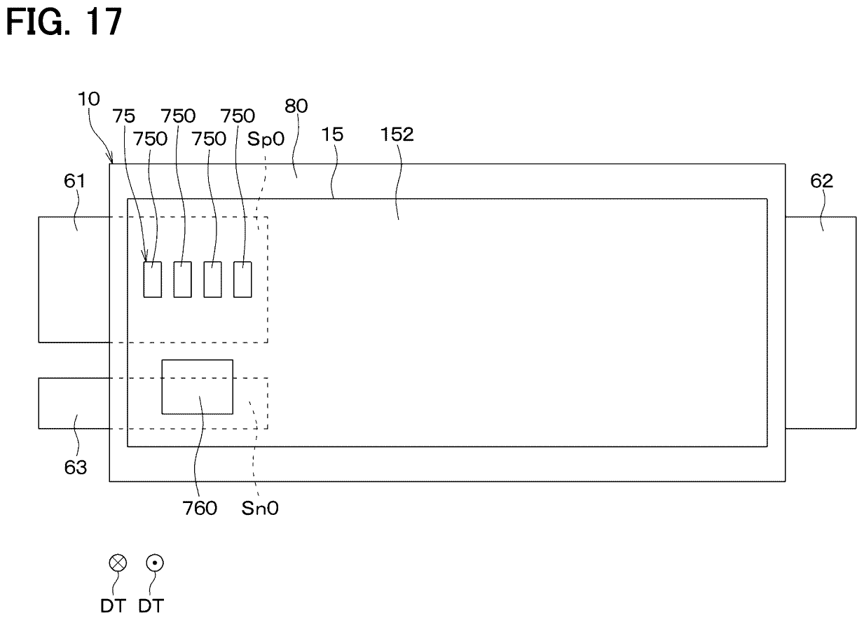

As shown in FIG. 17, the area of the surface of the P terminal 61 that faces the resistive element 750 in the thickness direction DT is referred to as Sp0. The area of the surface of the N terminal 63 that faces the capacitive element 760 in the thickness direction DT is referred to as Sn0. The P terminal 61 corresponds to the first terminal. The N terminal 63 corresponds to the second terminal.

The area Sp0 is greater than the area Sn0, that is, satisfies a relationship of Sp0>Sn0.

When the resistive element 750 is projected in the thickness direction DT, the entire resistive element 750 projected overlaps with the P terminal 61.

The semiconductor device 10 of the fifth embodiment is configured as described above. The fifth embodiment achieves effects similar to the effects achieved by the first embodiment. The fifth embodiment also achieves the following effects.
(3) Since the relationship of Sp0>Sn0 is satisfied, the amount of heat transferred from the resistive element 750 to the P terminal 61 is greater than that in a configuration satisfying a relationship of Sp0≤Sn0. Therefore, the increase in temperature of the resistive element 750 is suppressed.

### Sixth Embodiment

In a sixth embodiment, the configuration of the P terminal 61 is different from that in the first embodiment. The other configurations are similar to those of the first embodiment.

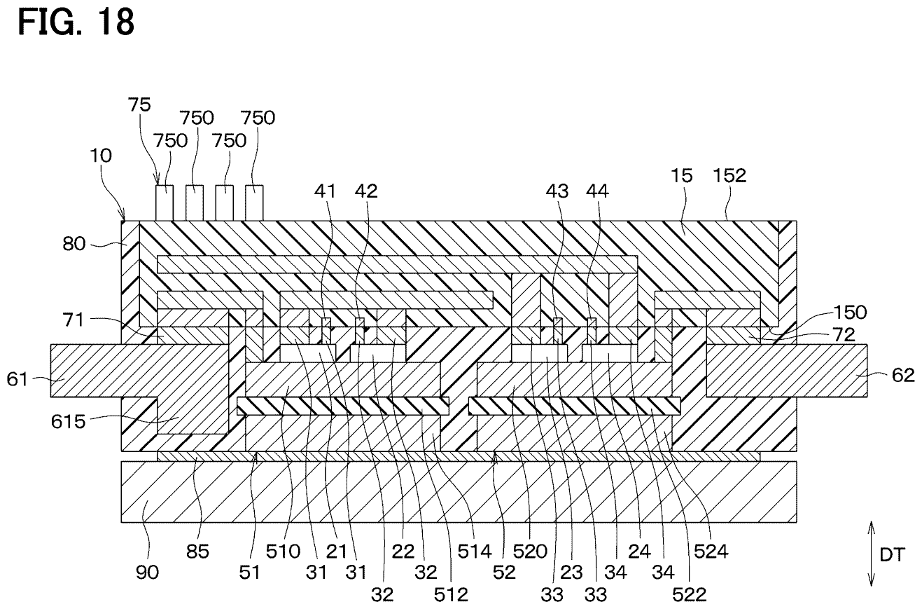

Specifically, the P terminal 61 has a protrusion 615, as shown in FIG. 18. The protrusion 615 protrudes from a part of the P terminal 61 that overlaps with the resistive element 750 toward the cooler 90. Furthermore, the protrusion 615 is formed into the shape of a quadrangular pillar. However, the shape of the protrusion 615 is not limited to the quadrangular pillar. The protrusion 615 may have any shape, such as a cylindrical shape, an arcuate pillar shape, or a hemispherical shape.

The semiconductor device 10 of the sixth embodiment is configured as described above. The sixth embodiment achieves effects similar to the effects achieved by the first embodiment. The sixth embodiment also achieves the following effects.
(4) The P terminal 61 has the protrusion 615. The protrusion 615 facilitates the heat from the P terminal 61 to be transferred to the cooler 90. For this reason, the heat generated in the resistive element 750 is easily transferred to the cooler 90 through the P terminal 61. Therefore, the heat generated in the resistive element 750 is easily dissipated, and the increase in temperature of the resistive element 750 is suppressed.

### Seventh Embodiment

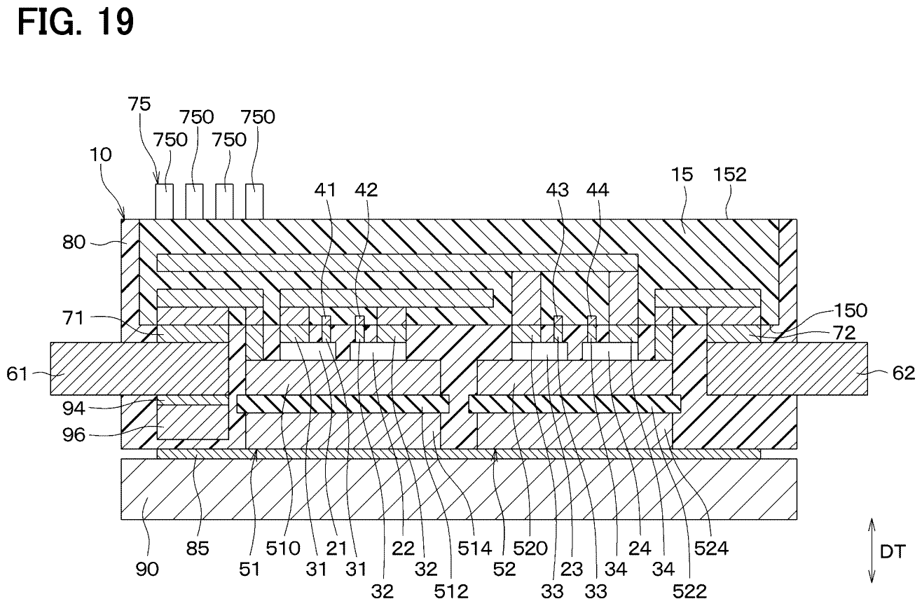

In the seventh embodiment, the semiconductor device 10 further includes a connection member 94 and a heat transfer member 96, as shown in FIG. 19. The other configurations are similar to those of the first embodiment.

The connection member 94 is connected to a part of the P terminal 61 that overlaps with the resistive element 750. The connection member 94 is, for example, solder, sintered silver, adhesive, or the like.

The heat transfer member 96 is made of copper or the like. Therefore, the thermal conductivity of the heat transfer member 96 is relatively high. Furthermore, the heat transfer member 96 is connected to the connection member 94 on a side opposite to the P terminal 61. The heat transfer member 96 protrudes from a boundary with the connection member 94 toward the cooler 90. The heat transfer member 96 is formed into the shape of a quadrangular pillar. However, the shape of the heat transfer member 96 is not limited to the quadrangular pillar. The heat transfer member 96 may have any shape, such as a cylindrical shape, an arcuate pillar shape, a hemispherical shape, or the like.

The semiconductor device 10 of the seventh embodiment is configured as described above. The seventh embodiment achieves effects similar to the effects achieved by the first embodiment. The seventh embodiment also achieves the following effects.
(5) The semiconductor device 10 further includes the connection member 94 and the heat transfer member 96. Therefore, the heat from the P terminal 61 is easily transferred to the cooler 90. As a result, the heat generated in the resistive element 750 is easily transferred to the cooler 90 through the P terminal 61. Since the heat generated in the resistive element 750 is easily dissipated, the increase in temperature of the resistive element 750 is suppressed.

### Eighth Embodiment

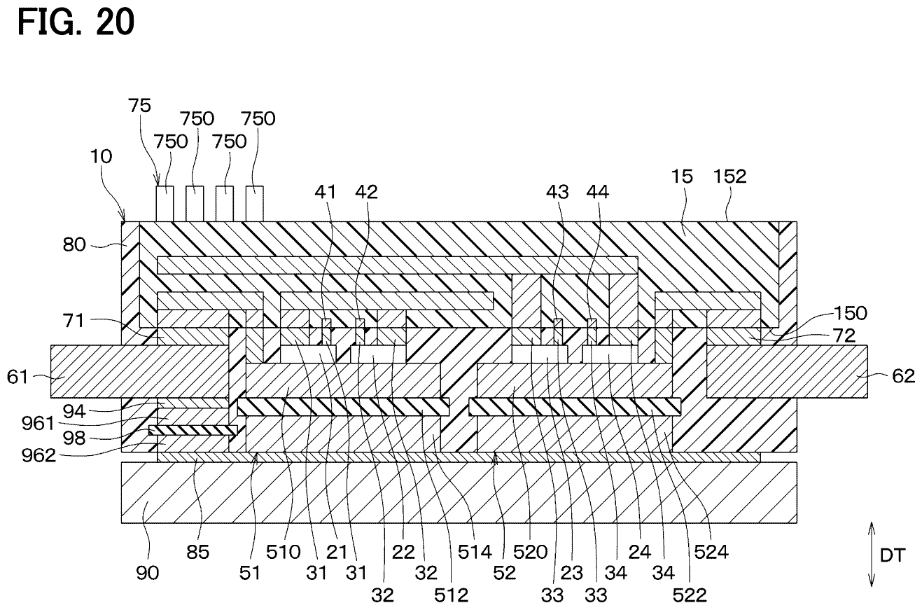

In an eighth embodiment, the semiconductor device 10 further includes a connection member 94, a first heat transfer member 961, an insulating member 98, and a second heat transfer member 962, as shown in FIG. 20. The other configurations are similar to those of the first embodiment.

The connection member 94 is connected to a part of the P terminal 61 that overlaps with the resistive element 750. The connection member 94 is, for example, solder, sintered silver, adhesive, or the like.

The first heat transfer member 961 is made of copper or the like. Therefore, the thermal conductivity of the first heat transfer member 961 is relatively high. Furthermore, the first heat transfer member 961 is connected to the connection member 94 on a side opposite to the P terminal 61. The first heat transfer member 961 has a plate shape. However, the shape of the first heat transfer member 961 is not limited to the plate shape. The first heat transfer member 961 may have any shape, such as a cylindrical shape, an arcuate pillar shape, or a hemispherical shape.

The insulating member 98 is made of ceramics or the like. Therefore, the insulating member 98 is electrically insulating. Furthermore, the insulating member 98 is connected to the first heat transfer member 961 on a side opposite to the connection member 94. The insulating member 98 has a plate shape. However, the shape of the insulating member 98 is not limited to the plate shape. The insulating member 98 may have any shape such as a cylindrical shape, an arcuate pillar shape, or a hemispherical shape.

The second heat transfer member 962 is made of copper or the like. Therefore, the thermal conductivity of the second heat transfer member 962 is relatively high. Furthermore, the second heat transfer member 962 is connected to the insulating member 98 on a side opposite to the first heat transfer member 961. The second heat transfer member 962 has a plate shape. The second heat transfer member 962 constitutes the insulating circuit board, together with the first heat transfer member 961 and the insulating member 98. Furthermore, the second heat transfer member 962 faces the cooler 90 in the thickness direction DT. The surface of the second heat transfer member 962 opposite to the insulating member 98 is exposed from the encapsulating resin 80. Furthermore, the surface of the second heat transfer member 962 opposite to the insulating member 98 is connected to the thermal conductive member 85. The shape of the second heat transfer member 962 is not limited to the plate shape. The second heat transfer member 962 may have any shape, such as a cylindrical shape, an arcuate pillar shape, or a hemispherical shape.

The semiconductor device 10 of the eighth embodiment is configured as described above. The eighth embodiment achieves effects similar to the effects achieved by the first embodiment. The eighth embodiment also achieves the following effects.
(6) The semiconductor device 10 further includes the connection member 94, the first heat transfer member 961, the insulating member 98, and the second heat transfer member 962.

Therefore, the heat from the P terminal 61 is easily transferred to the cooler 90. With this, the heat generated in the resistive element 750 is easily transferred to the cooler 90 through the P terminal 61. As such, the heat generated in the resistive element 750 is easily dissipated, and the increase in temperature of the resistive element 750 is suppressed.

### Ninth Embodiment

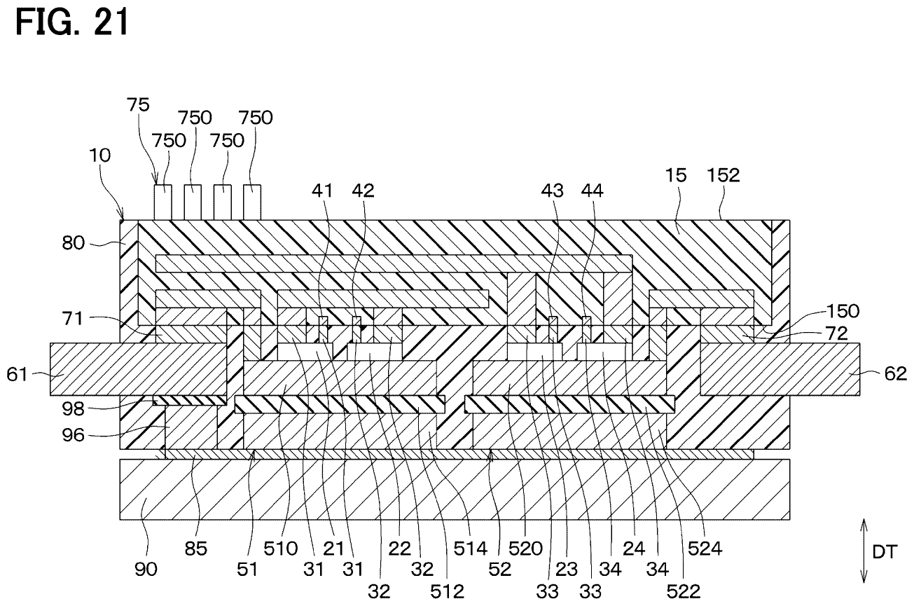

In a ninth embodiment, the semiconductor device 10 further includes a heat transfer member 96 and an insulating member 98, as shown in FIG. 21. The other configurations are similar to those of the first embodiment.

The heat transfer member 96 is made of copper or the like. Therefore, the thermal conductivity of the heat transfer member 96 is relatively high. Furthermore, the heat transfer member 96 is connected to the insulating member 98 (described later) on a side opposite to the P terminal 61. The heat transfer member 96 has a quadrangular pillar shape. The heat transfer member 96 faces the cooler 90 in the thickness direction DT. The surface of the heat transfer member 96 opposite to the insulating member 98 is exposed from the encapsulating resin 80. Furthermore, the surface of the heat transfer member 96 opposite to the insulating member 98 is connected to the thermal conductive member 85. The shape of the heat transfer member 96 is not limited to the quadrangular pillar shape, and the heat transfer member 96 may have any shape, such as a cylindrical shape, an arcuate pillar shape or a hemispherical shape.

The insulating member 98 is made of resin, ceramics, or the like. Therefore, the insulating member 98 is electrically insulating. The insulating member 98 is connected to a part of the P terminal 61 that overlaps with the resistive element 750 through an adhesive or the like. Furthermore, the insulating member 98 has a quadrangular pillar shape. The shape of the insulating member 98 is not limited to the quadrangular pillar, and the insulating member 98 may have any shape such as a cylindrical shape, an arcuate pillar shape, or a semispherical shape.

The semiconductor device 10 of the ninth embodiment is configured as described above. The ninth embodiment achieves effects similar to the effects achieved by the first embodiment. The ninth embodiment also achieves the following effects.
(7) The semiconductor device 10 further includes the insulating member 98 and the heat transfer member 96. Therefore, the heat from the P terminal 61 is easily transferred to the cooler 90. With this, the heat generated in the resistive element 750 is easily transferred to the cooler 90 via the P terminal 61. As such, the heat generated in the resistive element 750 is easily dissipated, and the increase in temperature of the resistive element 750 is suppressed.

### Tenth Embodiment

In a tenth embodiment, the configuration of the thermal conductive member 85 is different from that in the first embodiment. The other configurations are similar to those of the first embodiment.

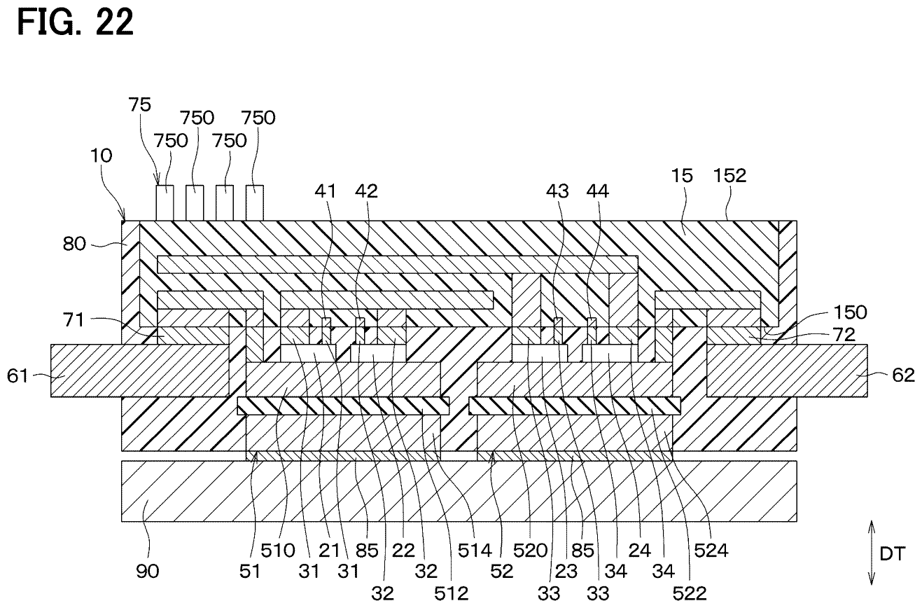

In the first embodiment, when the thermal conductive member 85 is projected in the thickness direction DT, the projected thermal conductive member 85 overlaps with the P terminal 61. On the other hand, in the tenth embodiment, when the thermal conductive member 85 is projected in the thickness direction DT, the projected thermal conductive member 85 does not overlap with the P terminal 61, as shown in FIG. 22.

The semiconductor device 10 of the tenth embodiment is configured as described above. The tenth embodiment achieves effects similar to the effects achieved by the first embodiment.

### Eleventh Embodiment

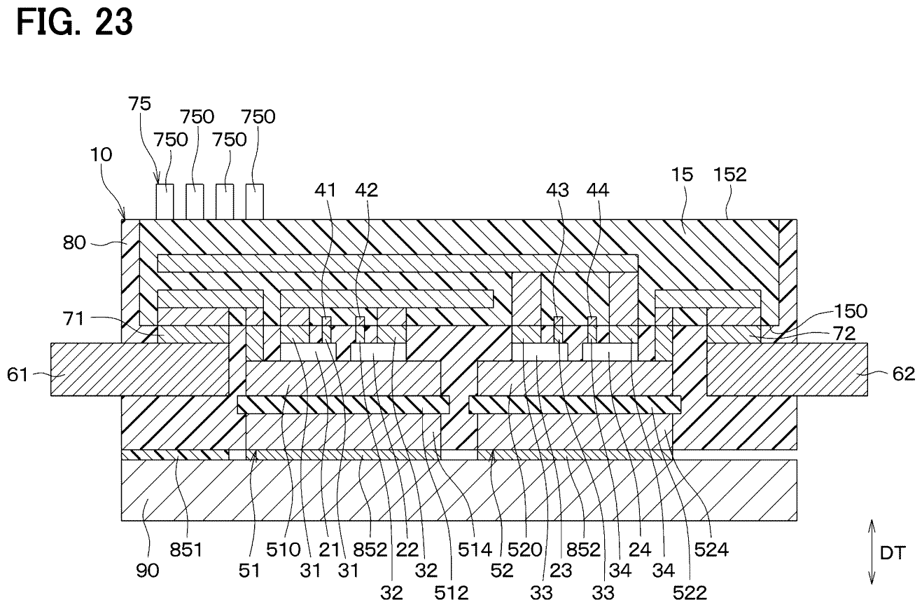

In an eleventh embodiment, the semiconductor device 10 includes a first thermal conductive member 851 and a second thermal conductive member 852, in place of the thermal conductive member 85, as shown in FIG. 23. The other configurations are similar to those of the first embodiment.

The first thermal conductive member 851 is made of an epoxy resin or the like for underfill and sidefill and is formed into a form of gel, sheet, or clay. Furthermore, the first thermal conductive member 851 is connected to a part of the encapsulating resin 80 and a part of the cooler 90, the parts overlapping with the P terminal 61 in the thickness direction DT. When first thermal conductive member 851 is projected in thickness direction DT, the projected first thermal conductive member 851 overlaps with the P terminal 61, the resistive element 750, and the cooler 90. Furthermore, when the first thermal conductive member 851 is projected in the thickness direction DT, the projected first thermal conductive member 851 does not overlap with the first semiconductor element 21, the second semiconductor element 22, the third semiconductor element 23, and the fourth semiconductor element 24.

The second thermal conductive member 852 is made of a material different from that of the first thermal conductive member 851 and is formed into a form of gel, sheet or clay. For example, the material of the second thermal conductive member 852 is solder, sintered silver, or the like. The second thermal conductive member 852 is connected to the exposed surface of the second heat dissipation portion 514 and the exposed surface of the fourth heat dissipation portion 524 in the thickness direction DT. Furthermore, when the second thermal conductive member 852 is projected in the thickness direction DT, the projected second thermal conductive member 852 overlaps with the first semiconductor element 21, the second semiconductor element 22, the third semiconductor element 23, the fourth semiconductor element 24 and the cooler 90. When second thermal conductive member 852 is projected in thickness direction DT, the projected second thermal conductive member 852 does not overlap with the P terminal 61 and the resistive element 750.

The semiconductor device 10 of the eleventh embodiment is configured as described above. The eleventh embodiment achieves effects similar to the effects achieved by the first embodiment. The eleventh embodiment also achieves the following effects.
(8) The semiconductor device 10 includes the first thermal conductive member 851 and the second thermal conductive member 852. The material of the first thermal conductive member 851 is different from the material of the second thermal conductive member 852. The first thermal conductive member 851 contains an epoxy resin. Therefore, the connection of the first thermal conductive member 851 with the encapsulating resin 80 and the cooler 90 is relatively strong.

### Twelfth Embodiment

In a twelfth embodiment, the configurations of the P terminal 61 and the first heat dissipation member 51 are different from those in the first embodiment. The other configurations are similar to those of the first embodiment.

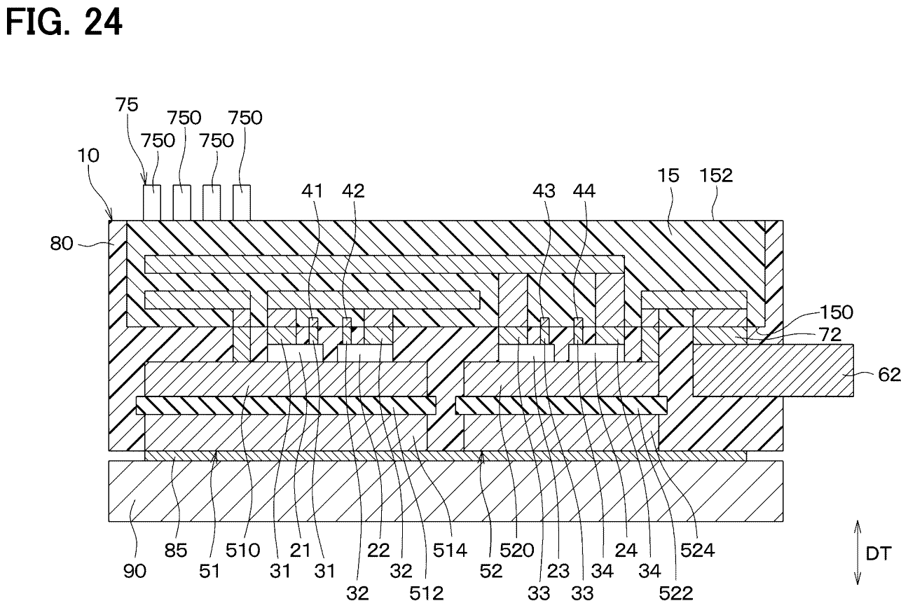

Specifically, as shown in FIG. 24, when the resistive element 750 is projected in the thickness direction DT, the projected resistive element 750 does not overlap with the P terminal 61.

The first heat dissipation portion 510, the first insulating portion 512, and the second heat dissipation portion 514 of the first heat dissipation member 51 extend in a direction perpendicular to the thickness direction DT. As a result, when the resistive element 750 is projected in the thickness direction DT, the projected resistive element 750 overlaps with the first heat dissipation portion 510, the first insulating portion 512 and the second heat dissipation portion 514.

The semiconductor device 10 of the twelfth embodiment is configured as described above. The twelfth embodiment achieves effects similar to the effects achieved by the first embodiment.

### Thirteenth Embodiment

In a thirteenth embodiment, the configuration of the P terminal 61 is different from that in the twelfth embodiment. The other configurations are similar to those of the twelfth embodiment.

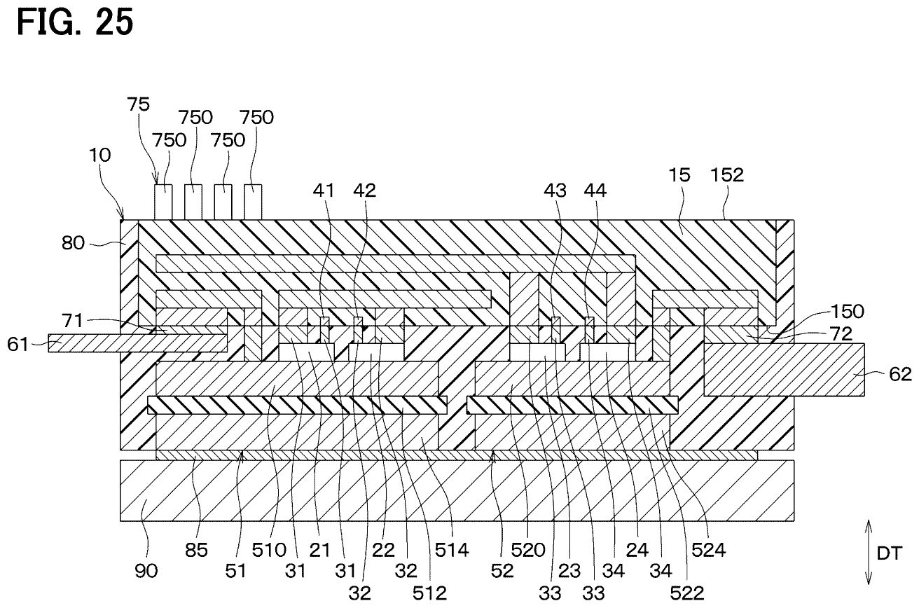

Specifically, as shown in FIG. 25, when the resistive element 750 is projected in the thickness direction DT, the projected resistive element 750 overlaps with the P terminal 61, differently from the twelfth embodiment in which the projected resistive element 750 does not overlap with the P terminal 61.

The semiconductor device 10 of the thirteenth embodiment is configured as described above. The thirteenth embodiment achieves effects similar to the effects achieved by the twelfth embodiment.

### Fourteenth Embodiment

In a fourteenth embodiment, the semiconductor device 10 further includes a connection member 94. The other configurations are similar to those of the thirteenth embodiment.

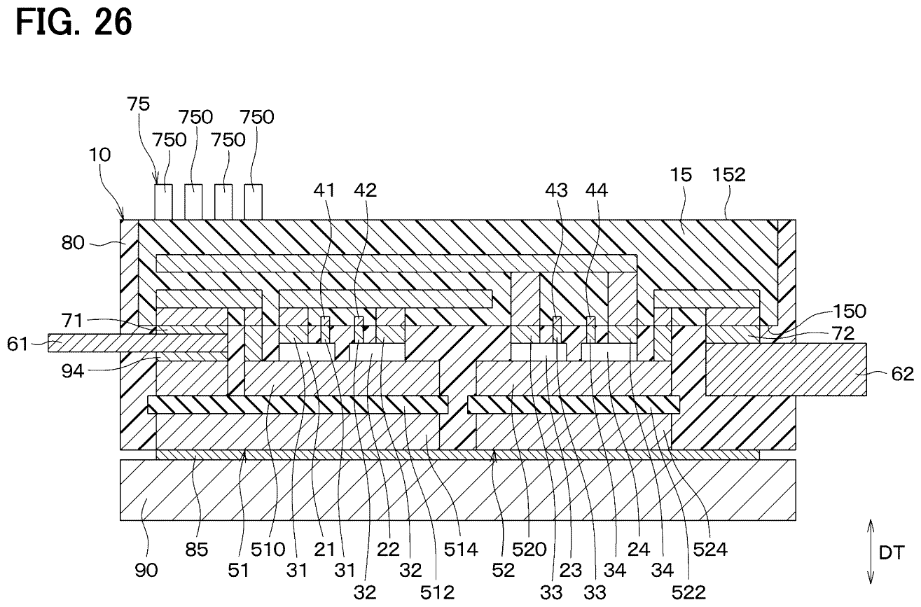

The connection member 94 is made of solder or the like. As shown in FIG. 26, the connection member 94 is connected to the P terminal 61 on a side opposite to the P terminal bonding material 71 in the thickness direction DT. Furthermore, the connection member 94 is connected to the first heat dissipation portion 510.

The semiconductor device 10 of the fourteenth embodiment is configured as described above. The fourteenth embodiment achieves effects similar to the effects achieved by the thirteenth embodiment.

### Fifteenth Embodiment

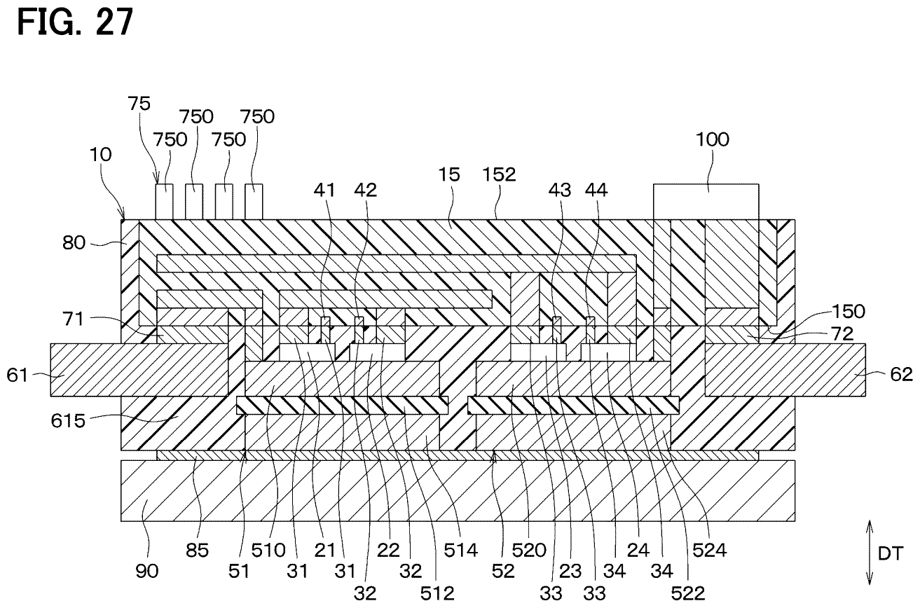

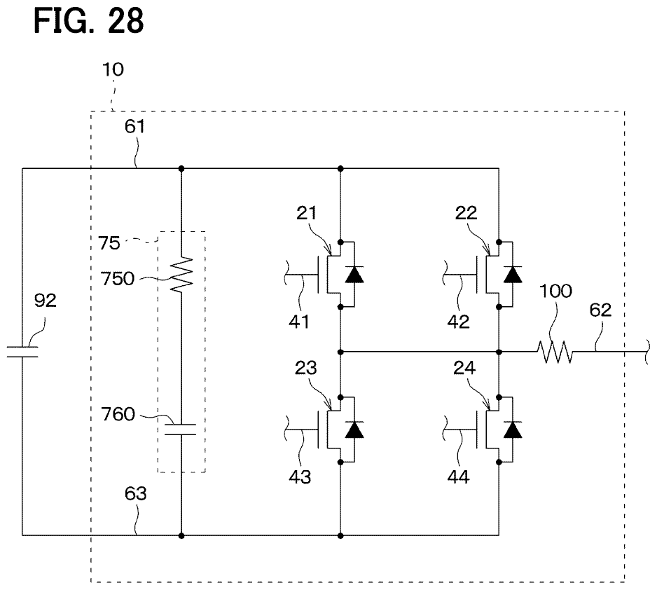

In a fifteenth embodiment, the semiconductor device 10 further includes a shunt resistor 100, as shown in FIGS. 27 and 28. The other configurations are similar to those of the first embodiment.

As shown in FIG. 27, the shunt resistor 100 is connected to the substrate back surface 152 in the thickness direction DT. When the shunt resistor 100 is projected in the thickness direction DT, the projected shunt resistor 100 overlaps with the O terminal 62, the thermal conductive member 85 and the cooler 90.

The shunt resistor 100 is connected to the source electrode of the first semiconductor element 21 through a via and a wiring layer disposed in the substrate 15 and the first semiconductor element bonding material 31. Furthermore, the shunt resistor 100 is connected to the source electrode of the second semiconductor element 22 through a via and a wiring layer disposed in the substrate 15 and the second semiconductor element bonding material 32. In addition, the shunt resistor 100 is connected to the drain electrode of the third semiconductor element 23 and the drain electrode of the fourth semiconductor element 24 through vias and wiring layers disposed in the substrate 15, the bonding material, and the third heat dissipation portion 520. Furthermore, the shunt resistor 100 is connected to the O terminal 62 through a via and a wiring layer disposed in the substrate 15 and an O terminal bonding material 72. Therefore, as shown in FIG. 28, one end of the shunt resistor 100 is connected to the source electrode of the first semiconductor element 21, the source electrode of the second semiconductor element 22, the drain electrode of the third semiconductor element 23, and the drain electrode of the fourth semiconductor element 24. The other end of the shunt resistor 100 is connected to the O terminal 62. Therefore, the shunt resistor 100 detects the electric current flowing through the O terminal 62, which is caused in accordance with the on and off states of the first semiconductor element 21, the second semiconductor element 22, the third semiconductor element 23, and the fourth semiconductor element 24.

The semiconductor device 10 of the fifteenth embodiment is configured as described above. The fifteenth embodiment achieves effects similar to the effects achieved by the first embodiment.

### Sixteenth Embodiment

In a sixteenth embodiment, the configurations of the first resistive element 751 and the second resistive element 752 are different from those in the fourth embodiment. The other configurations are similar to those of the fourth embodiment.

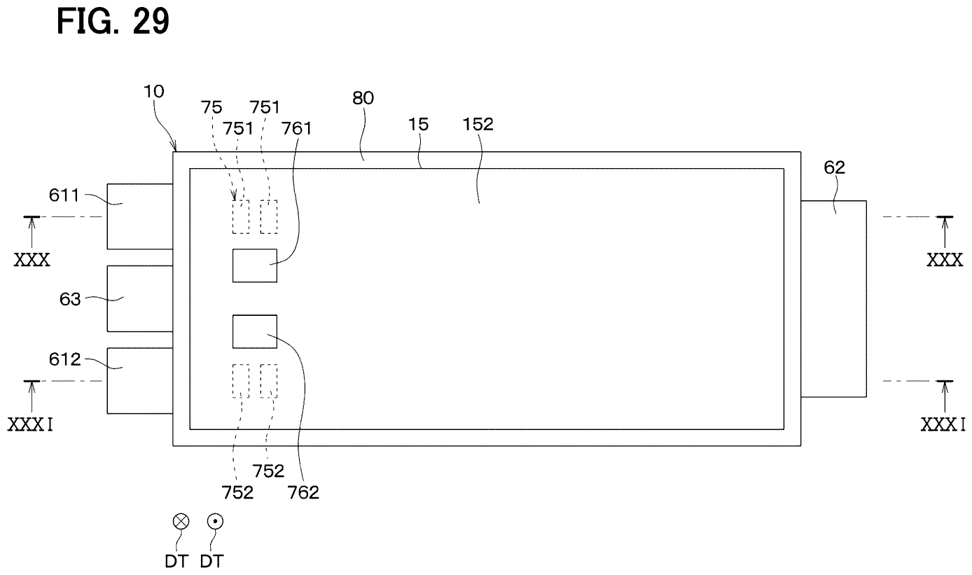

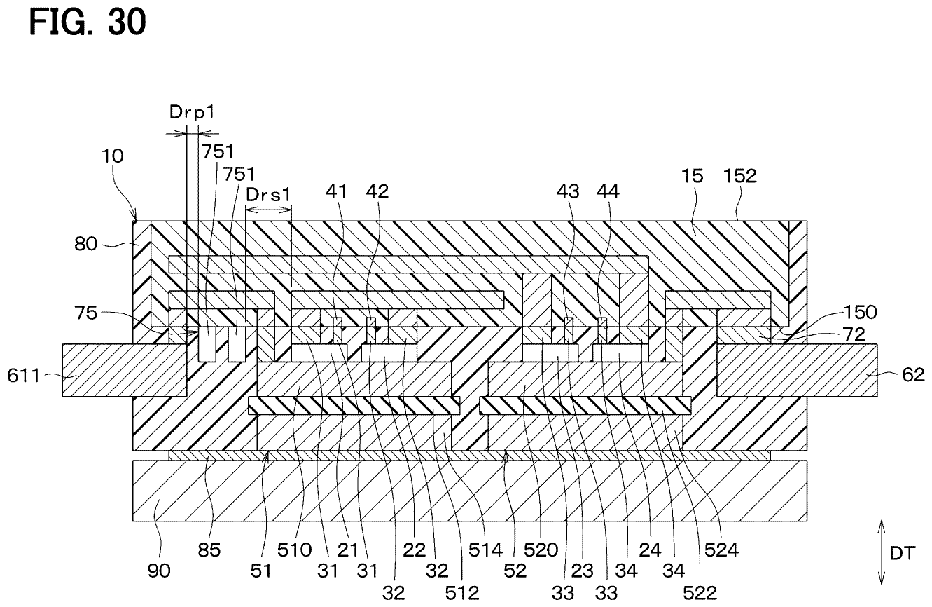

Specifically, as shown in FIGS. 29 and 30, the first resistive element 751 is connected to the substrate front surface 150 in the thickness direction DT, in place of the substrate back surface 152. As shown in FIG. 30, the first resistive element 751 is disposed between the first semiconductor element 21 and the first P terminal 611 in a direction perpendicular to the thickness direction DT. When the first resistive element 751 is projected in the thickness direction DT, the projected first resistive element 751 does not overlap with the first semiconductor element 21, the second semiconductor element 22, the third semiconductor element 23, the fourth semiconductor element 24, and the first P terminal 611. When the first resistive element 751 is projected in a direction perpendicular to the thickness direction DT, the projected first resistive element 751 overlaps with the first semiconductor element 21, the second semiconductor element 22, the third semiconductor element 23, the fourth semiconductor element 24, and the first P terminal 611.

In this case, a shortest distance from the first resistive element 751 to the first P terminal 611 in a direction perpendicular to the thickness direction DT is referred to as Drp1. A shortest distance from the first resistive element 751 to the first semiconductor element 21 in a direction perpendicular to the thickness direction DT is referred to as Drs1.

The distance Drp1 is shorter than the distance Drs1. That is, a relationship of Drp1<Drs1 is satisfied.

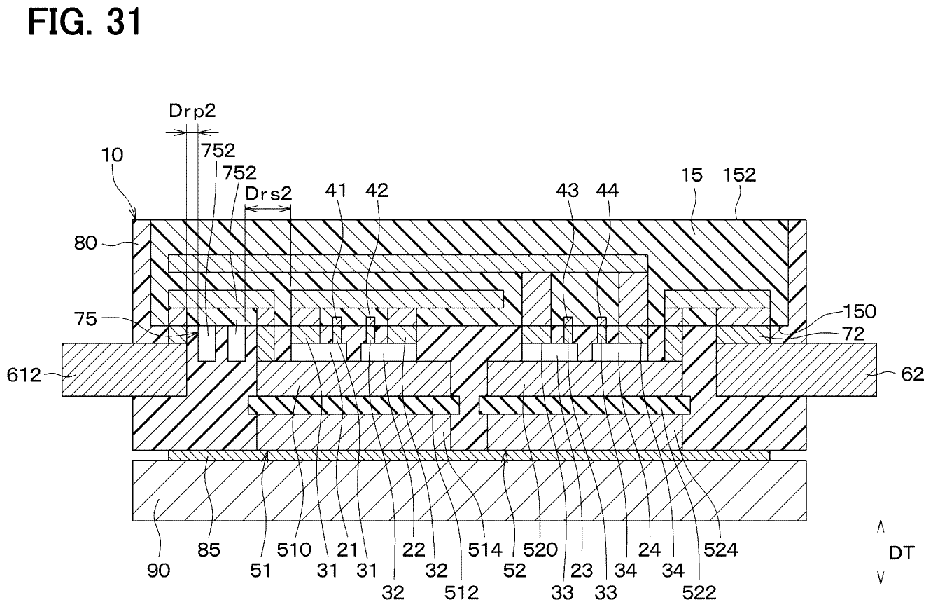

As shown in FIGS. 29 and 31, the second resistive element 752 is connected to the substrate front surface 150 in the thickness direction DT, in place of the substrate back surface 152. Furthermore, as shown in FIG. 31, the second resistive element 752 is disposed between the first semiconductor element 21 and the second P terminal 612 in a direction perpendicular to the thickness direction DT. When the second resistive element 752 is projected in the thickness direction DT, the projected second resistive element 752 does not overlap with the first semiconductor element 21, the second semiconductor element 22, the third semiconductor element 23, the fourth semiconductor element 24, and the second P terminal 612. When the second resistive element 752 is projected in a direction perpendicular to the thickness direction DT, the projected second resistive element 752 overlaps with the first semiconductor element 21, the second semiconductor element 22, the third semiconductor element 23, the fourth semiconductor element 24, and the second P terminal 612.

As shown in FIG. 31, a shortest distance from the second resistive element 752 to the second P terminal 612 in the direction perpendicular to the thickness direction DT is referred to as Drp2. A shortest distance from the second resistive element 752 to the first semiconductor element 21 in a direction perpendicular to the thickness direction DT is referred to as Drs2.

The distance Drp2 is shorter than the distance Drs2. That is, a relationship of Drp2<Drs2 is satisfied.

The semiconductor device 10 of the sixteenth embodiment is configured as described above. The sixteenth embodiment achieves effects similar to the effects achieved by the fourth embodiment.

### Seventeenth Embodiment

In a seventeenth embodiment, the configuration of the resistive element 750 is different from that in the first embodiment. The other configurations are similar to those of the first embodiment.

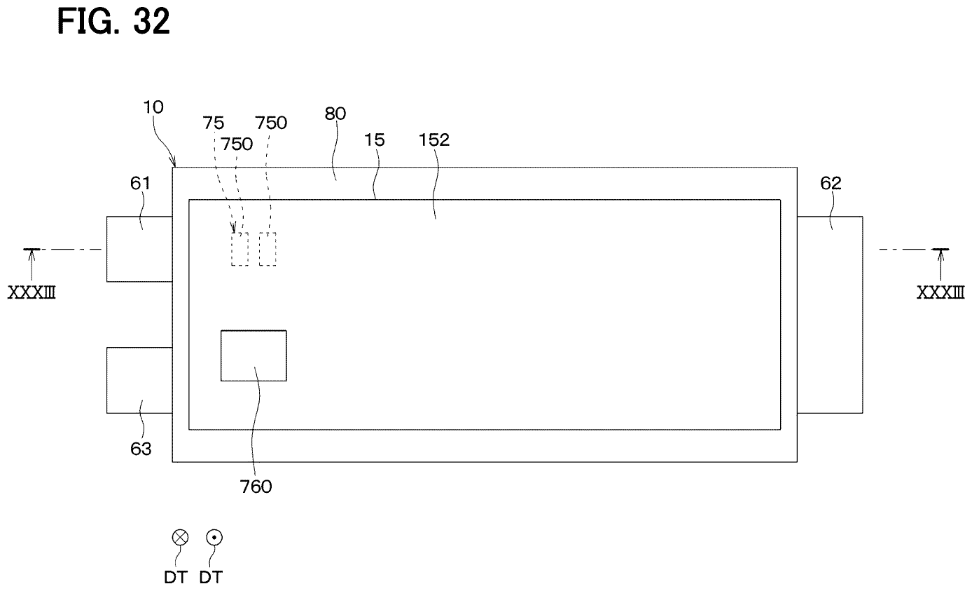

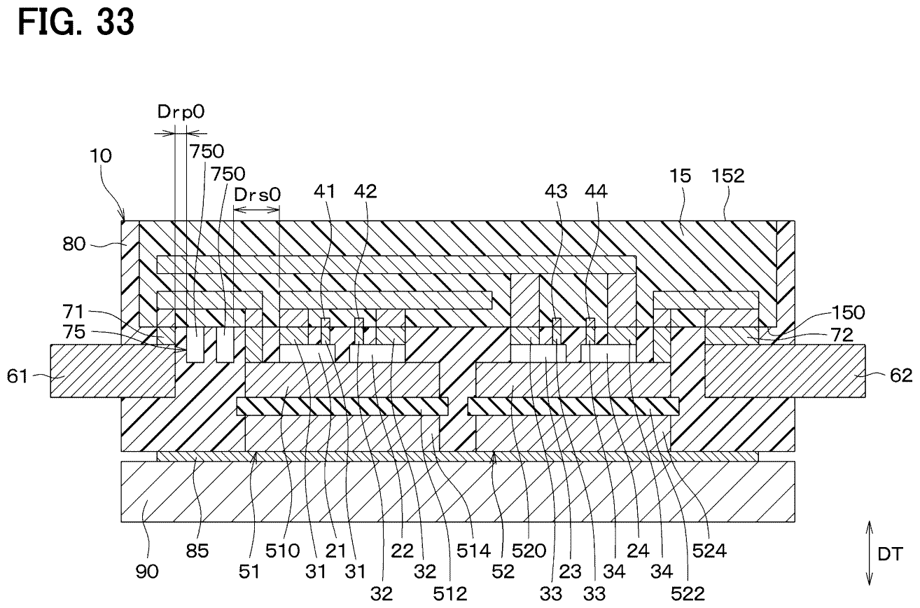

Specifically, as shown in FIGS. 32 and 33, the resistive element 750 is connected to the substrate front surface 150 in the thickness direction DT, in place of the substrate back surface 152. The resistive element 750 is disposed between the first semiconductor element 21 and the P terminal 61 in a direction perpendicular to the thickness direction DT. When the resistive element 750 is projected in the thickness direction DT, the projected resistive element 750 does not overlap with the first semiconductor element 21, the second semiconductor element 22, the third semiconductor element 23, the fourth semiconductor element 24 and the P terminal 61. When the resistive element 750 is projected in a direction perpendicular to the thickness direction DT, the projected resistive element 750 overlaps with the first semiconductor element 21, the second semiconductor element 22, the third semiconductor element 23, the fourth semiconductor element 24 and the P terminal 61.

Here, a shortest distance from the resistive element 750 to the P terminal 61 in a direction perpendicular to the thickness direction DT is referred to as Drp0. A shortest distance from the resistive element 750 to the first semiconductor element 21 in a direction perpendicular to the thickness direction DT is referred to as Drs0.

The distance Drp0 is shorter than the distance Drs0. That is, a relationship of Drp0<Drs0 is satisfied.

The semiconductor device 10 of the seventeenth embodiment is configured as described above. The seventeenth embodiment achieves effects similar to the effects achieved by the first embodiment.

### Other Embodiments

The present disclosure is not limited to the embodiments described above, and the embodiments described above can be appropriately modified. The constituent element(s) of each of the embodiments described above is/are not necessarily essential unless it is specifically stated that the constituent element(s) is/are essential in the embodiment, or unless the constituent element(s) is/are obviously essential in principle.

In each of the embodiments described above, the first semiconductor element 21, the second semiconductor element 22, the third semiconductor element 23, and the fourth semiconductor element 24 are MOSFETs. On the other hand, the first semiconductor element 21, the second semiconductor element 22, the third semiconductor element 23, and the fourth semiconductor element 24 are not limited to the MOSFETs, and may be, for example, IGBT elements or the like. IGBT is an abbreviation for Insulated Gate Bipolar Transistor.

In each of the embodiments described above, the P terminal 61, the O terminal 62, the N terminal 63, the first P terminal 611, and the second P terminal 612 are each formed into a plate shape. On the other hand, the shape of each of the P terminal 61, the O terminal 62, the N terminal 63, the first P terminal 611 and the second P terminal 612 is not limited to the plate shape, but may be formed into a rod shape such as a cylindrical or arcuate-pillar shape, for example.

In each of the embodiments described above, the resistive element 750, the first resistive element 751, and the second resistive element 752 of the snubber circuit 75 are illustrated as the heat generating components. On the other hand, the heat generating components are not limited to the first resistive element 751 and the second resistive element 752 of the snubber circuit 75. The heat generating component may be, for example, the shunt resistor 100.

In each of the embodiments described above, the first heat dissipation member 51 and the second heat dissipation member 52 are insulating circuit boards. On the other hand, the first heat dissipation member 51 and the second heat dissipation member 52 are not limited to being the insulating circuit boards, and may be, for example, copper plates or the like.

In each of the embodiments described above, the substrate back surface 152 is exposed from the encapsulating resin 80. On the other hand, it is not always necessary that the substrate back surface 152 is exposed from the encapsulating resin 80. The substrate back surface 152 of the substrate may be covered by the encapsulating resin 80 without being exposed from the encapsulating resin 80.

In each of the embodiments described above, the second heat dissipation portion 514 and the fourth heat dissipation portion 524 are exposed from the encapsulating resin 80. On the other hand, it is not always necessary that the second heat dissipation portion 514 and the fourth heat dissipation portion 524 are exposed from the encapsulating resin 80. The second heat dissipation portion 514 and the fourth heat dissipation portion 524 may be covered by the encapsulating resin 80 without being exposed from the encapsulating resin 80.

In the eighth embodiment described above, the second heat transfer member 962 is exposed from the encapsulating resin 80. On the other hand, it is not necessary that the second heat transfer member 962 is exposed from the encapsulating resin 80. The second heat transfer member 962 may be covered by the encapsulating resin 80 without being exposed from the encapsulating resin 80.

In the ninth embodiment described above, the heat transfer member 96 is exposed from the encapsulating resin 80. On the other hand, it is not always necessary that the heat transfer member 96 is exposed from the encapsulating resin 80. The heat transfer member 96 may be covered by the encapsulating resin 80 without being exposed from the encapsulating resin 80.

The embodiments described above may be combined as appropriate.

What is claimed is:

1. A semiconductor device comprising:
a substrate;
a semiconductor element connected to a surface of the substrate;
a terminal being electrically conductive, and connected to the substrate; and
a heat generating component connected to the substrate and generating heat when an electric current flows therethrough, wherein
the heat generating component is disposed at a position overlapping with the terminal when the heat generating component is projected in a thickness direction of the substrate.

2. The semiconductor device according to claim 1, wherein
the heat generating component is disposed at a position without overlapping with the semiconductor element when the heat generating component is projected in the thickness direction of the substrate.

3. The semiconductor device according to claim 1, wherein
the terminal protrudes to an outside of the semiconductor device to be connected to a capacitor that supplies power to the semiconductor device.

4. The semiconductor device according to claim 1, wherein
the surface of the substrate to which the semiconductor element is connected a first surface of the substrate,
the substrate has a second surface opposite to the first surface in the thickness direction,
the terminal is connected to the second surface of the substrate, and
the heat generating component is connected to the first surface of the substrate.

5. The semiconductor device according to claim 1, wherein
the surface of the substrate to which the semiconductor element is connected a first surface of the substrate,
the substrate has a second surface opposite to the first surface in the thickness direction,
the terminal is connected to the first surface of the substrate, and
the heat generating component is connected to the second surface of the substrate,

6. The semiconductor device according to claim 5, further comprising:
a cooler that is disposed adjacent to the first surface of the substrate to cool the terminal, wherein
the cooler is disposed at a position overlapping with the terminal and the heat generating component when the cooler is projected in the thickness direction of the substrate.

7. The semiconductor device according to claim 6, wherein
the terminal has a protrusion protruding toward the cooler at a portion that overlaps with the heat generating component when the terminal is projected in the thickness direction of the substrate.

8. The semiconductor device according to claim 6, further comprising:
a connection member; and
a heat transfer member, wherein
the connection member is connected to a portion of the terminal overlapping with the heat generating component, and
the heat transfer member is connected to the connection member on a side opposite to the terminal, and protrudes from the connection member toward the cooler.

9. The semiconductor device according to claim 6, further comprising:
a connection member;
a first heat transfer member;
an insulating member; and
a second heat transfer member, wherein
the connection member is connected to a portion of the terminal overlapping with the heat generating component,
the first heat transfer member is connected to the connection member on a side opposite to the terminal,
the insulating member is electrically insulating and is connected to the first heat transfer member on a side opposite to the connection member, and
the second heat transfer member is connected to the insulating member on a side opposite to the first heat transfer member, and faces the cooler in the thickness direction of the substrate.

10. The semiconductor device according to claim 6, further comprising:
an insulating member; and
a heat transfer member, wherein
the insulating member is electrically insulating and is connected to a portion of the terminal overlapping with the heat generating component, and
the heat transfer member is connected to the insulating member on a side opposite to the terminal and faces the cooler in the thickness direction of the substrate.

11. The semiconductor device according to claim 6, further comprising:
a covering part; and
a thermal conductive member, wherein
the covering part covers the substrate, the semiconductor element, and the terminal,
the thermal conductive member is connected to the covering part and the cooler, and
the terminal is disposed at a position overlapping with the thermal conductive member when the terminal is projected in the thickness direction of the substrate.

12. The semiconductor device according to claim 11, wherein
the thermal conductive member is a first thermal conductive member,
the semiconductor device further comprising:
a heat dissipation member; and
a second thermal conductive member, wherein
the heat dissipation member is connected to the semiconductor element on a side opposite to the substrate and is covered by the covering part,
the second thermal conductive member is connected to the heat dissipation member and the cooler,
the second thermal conductive member is disposed at a position overlapping with the semiconductor element when the second thermal conductive member is projected in the thickness direction of the substrate, and
a material of the first thermal conductive member is different from a material of the second thermal conductive member.

13. The semiconductor device according to claim 12, wherein
the material of the first thermal conductive member includes an epoxy resin.

14. The semiconductor device according to claim 1, further comprising:
a snubber circuit including a resistive element and a capacitive element, wherein
the heat generating component is provided by the resistive element, and
the resistive element is disposed at a position entirely overlapping with the terminal when the resistive element is projected in the thickness direction of the substrate.

15. The semiconductor device according to claim 1, wherein
the terminal is a first terminal,
the semiconductor device further comprising:
a second terminal; and
a snubber circuit, wherein
the second terminal is electrically conductive, and is connected to a portion of the semiconductor element through the substrate, the portion being same as a portion of the semiconductor element to which the first terminal is connected,
the snubber circuit includes a first resistive element, a second resistive element, and a capacitive element,
the heat generating component is provided by the first resistive element and the second resistive element,
the first resistive element is disposed at a position overlapping with the first terminal when the first resistive element is projected in the thickness direction of the substrate, and
the second resistive element is disposed at a position overlapping with the second terminal when the second resistive element is projected in the thickness direction of the substrate.

16. The semiconductor device according to claim 1, wherein
the terminal is a first terminal,
the semiconductor device further comprising:
a second terminal; and
a snubber circuit, wherein
the second terminal is electrically conductive, and is connected to a portion of the semiconductor element through the substrate, the portion being same as a portion of the semiconductor element to which the first terminal is connected,
the snubber circuit includes a resistive element and a capacitive element,
the heat generating component is provided by the resistive element,
the resistive element is disposed at a position overlapping with the first terminal when the resistive element is projected in the thickness direction of the substrate,
the capacitive element is disposed at a position overlapping with the second terminal when the capacitive element is projected in the thickness direction of the substrate, and
an area of a surface of the first terminal facing the resistive element in the thickness direction is greater than an area of a surface of the second terminal facing the capacitive element in the thickness direction.

17. A semiconductor device comprising:
a substrate having a first surface and a second surface opposite to the first surface in a thickness direction of the substrate;
a semiconductor element connected to the first surface of the substrate;
a heat dissipation member connected to the semiconductor element on a side opposite to the substrate and extending in a direction perpendicular to the thickness direction of the substrate; and
a heat generating component connected to the second surface of the substrate and generating heat when an electric current flows therethrough, wherein
the heat generating component is disposed at a position overlapping with the heat dissipation member when the heat generating component is projected in the thickness direction of the substrate.

18. The semiconductor device according to claim 17, further comprising:
a terminal being electrically conductive, and connected to the first surface of the substrate, wherein
the heat generating component is disposed at a position overlapping with the heat dissipation member and the terminal when the heat generating component is projected in the thickness direction of the substrate.

19. The semiconductor device according to claim 18, further comprising:
a connection member connected to the heat dissipation member and the terminal.

20. The semiconductor device according to claim 18, wherein
the terminal protrudes to an outside of the semiconductor device to be connected to a capacitor that supplies power to the semiconductor device.

21. The semiconductor device according to claim 17, wherein
the heat generating component is disposed at a position without overlapping with the semiconductor element when the heat generating component is projected in the thickness direction of the substrate.

22. A semiconductor device comprising:
a substrate;
a semiconductor element connected to a surface of the substrate;
a terminal being electrically conductive, and connected to the surface of the substrate; and
a heat generating component connected to the surface of the substrate and generating heat when an electric current flows therethrough, wherein
a distance from the heat generating component to the terminal in a direction perpendicular to a thickness direction of the substrate is shorter than a distance from the heat generating component to the semiconductor element in a direction perpendicular to the thickness direction of the substrate.
